(19) United States
(12) Patent Application Publication
(10) Pub. No.: US 2025/0330124 A1
(43) Pub. Date: Oct. 23, 2025

(54) METHODS AND APPARATUS TO REGULATE A COMMON MODE VOLTAGE OF AN AMPLIFIER

(71) Applicant: Texas Instruments Incorporated, Dallas, TX (US)

(72) Inventors: Zhenzhen Chen, Shanghai (CN); Jianquan Liao, Shanghai (CN); Fanzhe Meng, Jiangsu (CN)

(21) Appl. No.: 18/642,427

(22) Filed: Apr. 22, 2024

(51) Int. Cl. H03F 1/02; H03F 1/26

(52) U.S. Cl. CPC H03F 1/0211; H03F 1/26; H03F 2200/372

(57) ABSTRACT

An example apparatus includes: current source circuitry having a first terminal, a second terminal, a third terminal, and a fourth terminal; current sink circuitry having a first terminal, a second terminal, a third terminal, and a fourth terminal; common mode voltage circuitry having a first terminal and a second terminal, the first terminal of the common mode voltage circuitry coupled to the first terminal of the current source circuitry and the first terminal of the current sink circuitry, the second terminal of the common mode voltage circuitry coupled to the second terminal of the current source circuitry and the second terminal of the current sink circuitry; idle current source circuitry having a terminal coupled to the third terminal of the current source circuitry; and feedback current source circuitry having a terminal coupled to the fourth terminal of the current source circuitry.

### TECHNICAL FIELD

This description relates generally to regulating common mode voltages and, more particularly, to methods and apparatus to regulate a common mode voltage of an amplifier.

### BACKGROUND

Electronic systems utilize amplifier circuitry for a wide range of operations, such as for signal modulation. Such amplifier circuitry generates a modulated output signal by modulating a carrier signal in accordance with an information signal. A load performs operations responsive to characteristics of the modulated output signal. In audio systems, amplifier circuitry modulates a carrier signal in accordance with an information signal to generate a modulated output signal that is a relatively higher power signal and relatively high noise immunity than the information signal. Using amplifier circuitry for signal modulation allows electronic systems to generate increasingly complex signals from relatively less complex signals.

### SUMMARY

For methods and apparatus to regulate a common mode voltage of an amplifier, an example apparatus includes current source circuitry having a first terminal, a second terminal, a third terminal, and a fourth terminal; current sink circuitry having a first terminal, a second terminal, a third terminal, and a fourth terminal; common mode voltage circuitry having a first terminal and a second terminal, the first terminal of the common mode voltage circuitry coupled to the first terminal of the current source circuitry and the first terminal of the current sink circuitry, the second terminal of the common mode voltage circuitry coupled to the second terminal of the current source circuitry and the second terminal of the current sink circuitry; idle current source circuitry having a first terminal and a second terminal, the first terminal of the idle current source circuitry coupled to the third terminal of the current source circuitry; and feedback current source circuitry having a first terminal, a second terminal, and a third terminal, the first terminal of the feedback current source circuitry is coupled to the fourth terminal of the current source circuitry, the second terminal of the feedback current source circuitry is coupled to the second terminal of the current sink circuitry, the third terminal of the feedback current source circuitry coupled to the fourth terminal of the current sink circuitry and the second terminal of the idle current source circuitry. Other examples are described.

For methods and apparatus to regulate a common mode voltage of an amplifier, an example apparatus includes amplifier circuitry having a first terminal, a second terminal, and a third terminal; a resistor having a first terminal and a second terminal the first terminal of the resistor coupled to the first terminal of the amplifier circuitry; and common mode regulator circuitry including: current source circuitry having a first terminal and a second terminal; current sink circuitry having a first terminal and a second terminal; and common mode voltage circuitry having a first terminal and a second terminal, the first terminal of the common mode voltage circuitry coupled to the second terminal of the amplifier circuitry, the second terminal of the resistor, the first terminal of the current source circuitry, and the first terminal of the current sink circuitry, the second terminal of the common mode voltage circuitry coupled to the third terminal of the amplifier circuitry, the second terminal of the current source circuitry, and the second terminal of the current sink circuitry. Other examples are described.

For methods and apparatus to regulate a common mode voltage of an amplifier, an example apparatus includes amplifier circuitry having an input and an output, the amplifier circuitry configured to generate an output signal at the output responsive to an input signal received at the input; a resistor coupled between the input of the amplifier circuitry and the output of the amplifier circuitry; and common mode regulator circuitry coupled to the input of the amplifier circuitry and to the resistor, the common mode regulator circuitry configured to: set a common mode voltage of the input of the amplifier circuitry; supply a first current to compensate the common mode voltage responsive to currents of the resistor; and sink a second current to compensate the common mode voltage responsive to currents of the resistor. Other examples are described.

### BRIEF DESCRIPTION OF THE DRAWINGS

FIG. 1 is a block diagram of an example audio system including example multi-class modulation circuitry and example common mode regulator circuitry to regulate a common mode voltage of an input signal.

FIG. 2 is a block diagram of an example of the multi-class modulation circuitry of FIG. 1.

FIG. 3 is a block diagram of an example of the common mode regulator circuitry of FIG. 1.

FIG. 4 is a schematic diagram of an example of the common mode regulator circuitry of FIGS. 1 and 3.

FIG. 5 is a flowchart representative of example operations that may be at least one of executed, instantiated, or performed to implement the common mode regulator circuitry of FIGS. 1, 3, and 4.

FIG. 6 is another flowchart representative of example operations that may be at least one of executed, instantiated, or performed to implement the common mode regulator circuitry of FIGS. 1, 3, and 4.

FIG. 7 is yet another flowchart representative of example operations that may be at least one of executed, instantiated, or performed to implement the common mode regulator circuitry of FIGS. 1, 3, and 4.

FIG. 8 is a plot of example operations of an input of the multi-class modulation circuitry of FIGS. 1 and 2 as the common mode regulator circuitry of FIGS. 1, 3, and 4 turns on and off.

FIG. 9 are plots of example common mode voltages of the multi-class modulation circuitry of FIGS. 1 and 2 with and without the common mode regulation circuitry of FIGS. 1, 3, and 4 across a range of output supply voltages and feedback ratios.

FIG. 10A is a plot of example resistance of the common mode regulator circuitry of FIGS. 1, 3, and 4 across a range of analog gains of the multi-class modulation circuitry of FIGS. 1 and 2.

FIG. 10B is a plot of example common mode resistances of the common mode regulator circuitry of FIGS. 1, 3, and 4 across a range of output supply voltages of the multi-class modulation circuitry of FIGS. 1 and 2.

FIG. 11 is a plot of example input common mode voltages of the common mode regulator circuitry of FIGS. 1 and 2 across a range of analog gains of the multi-class modulation circuitry of FIGS. 1 and 2.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Electronic systems utilize amplifier circuitry for a wide range of operations, such as for signal modulation. Such amplifier circuitry generates a modulated output signal by modulating a carrier signal in accordance with an information signal. The modulated output signal causes a load to perform operations responsive to characteristics of the modulated output signal. In audio systems, amplifier circuitry modulates a carrier signal in accordance with an information signal to generate a modulated output signal that is a relatively higher power signal and relatively high noise immunity than the information signal. Using amplifier circuitry for signal modulation allows electronic systems to generate relatively complex signals from relatively less complex signals.

As electronics continue to advance, signal modulation techniques continue to become increasingly complex. A method of single inductor (1L) modulation utilizes class AB and class D amplifier circuitry to modulate information of an input signal. The class AB and class D amplifier circuitry receive a sinusoidal signal as an information signal to be modulated. The class AB amplifier circuitry modulates the sinusoidal signal to generate a linear output signal. The linear output signal linearly transitions between logic levels, such as a linear transition from a logic high to a logic low. The class D amplifier circuitry modulates the sinusoidal input signal by comparing the sinusoidal signal to a triangular waveform, which represents the carrier signal. The class D amplifier circuitry generates a digital output signal having a varying duty cycle to represent the sinusoidal input signal. The duty cycle of the digital output signal represents amplitudes of the sinusoidal input signal. The class AB and class D amplifier circuitry also step up the input signal from an input power domain to an output power domain.

In some systems, the class AB and class D amplifier circuitry generate the output signal using a twenty-volt output supply voltage while the input signal uses a five-volt input supply voltage. In such systems, structuring the class D amplifier circuitry for closed loop operations increases the accuracy of the output signal. However, the differences between the power domain of the input signal and the power domain of the output signal result in relatively large feedback currents flowing through the current path between the input and output of the amplifier circuitry. Such currents modify the common mode of the input signal. In audio systems, when modulating an audio input signal, changes in the common mode of the audio input signal are amplified by the amplifier circuitry and result in undesirable audio disturbances (e.g., audio clipping).

Some systems prevent such common mode errors by including common mode regulator circuitry to regulate the common mode voltage at the input of the amplifier circuitry. In such systems, the common mode regulator circuitry includes current feedback circuitry and an error amplifier. The current feedback circuitry monitors voltages at the output of the amplifier circuitry to determine a feedback current. The feedback current represents the current flowing through a current path between an input and output of the amplifier circuitry. The current feedback circuitry sinks the feedback current from the amplifier circuitry and the error amplifier. The error amplifier compares a common mode voltage at the input of the amplifier circuitry to a reference voltage. The error amplifier supplies a current based on the comparison to the current feedback circuitry, which sets the common mode voltage at the input of the amplifier circuitry. However, at startup or during an idle time (e.g., the feedback current is approximately zero), the error amplifier continues to correct for a voltage difference between the common mode voltage at the input of the amplifier circuitry and the reference voltage. During such operations, excess current from the error amplifier creates a voltage spike at the input of the amplifier circuitry. In audio systems, the amplifier circuitry amplifies the voltage spike and produces an output signal that generates an undesirable audio disturbance (e.g., a pop).

Examples described herein include methods and apparatus to regulate a common mode voltage of an amplifier circuitry using common mode regulator circuitry. In some described examples, the common mode regulator circuitry includes idle current source circuitry, feedback current source circuitry, current source circuitry, and current sink circuitry. The idle current source circuitry receives an input supply voltage and an output supply voltage, which represent power domains of the input and output of the amplifier circuitry. The idle current source circuitry generates an idle current responsive to the input and output supply voltages. The idle current represents the feedback current of the amplifier during idle operations (e.g., no input signal is being supplied or an amplitude of the input signal is less than a threshold). The feedback current source circuitry receives the output voltage of the amplifier. The feedback current source circuitry generates a feedback current that is proportional to the current flowing through the current path between the input and output of the amplifier.

The current source circuitry and the current sink circuitry compare the idle current to the feedback current. When the idle current is greater than the feedback current, the current source circuitry supplies a first current, which is equal to the idle current minus the feedback current. When the feedback current is greater than the idle current, the current sink circuitry sinks a second current, which is equal to the feedback current minus the idle current. The common mode regulator circuitry regulates the common mode voltage at the input of the amplifier by supplying and sinking current to/from the input of the amplifier. Advantageously, during start up and idle operations, the common mode regulator circuitry does not source or sink currents responsive to the feedback current being equal to the idle current. Advantageously, the common mode regulator circuitry reduces voltage spikes at the input of the amplifier circuitry, which in audio systems reduces the likelihood of generating undesirable audio disturbances.

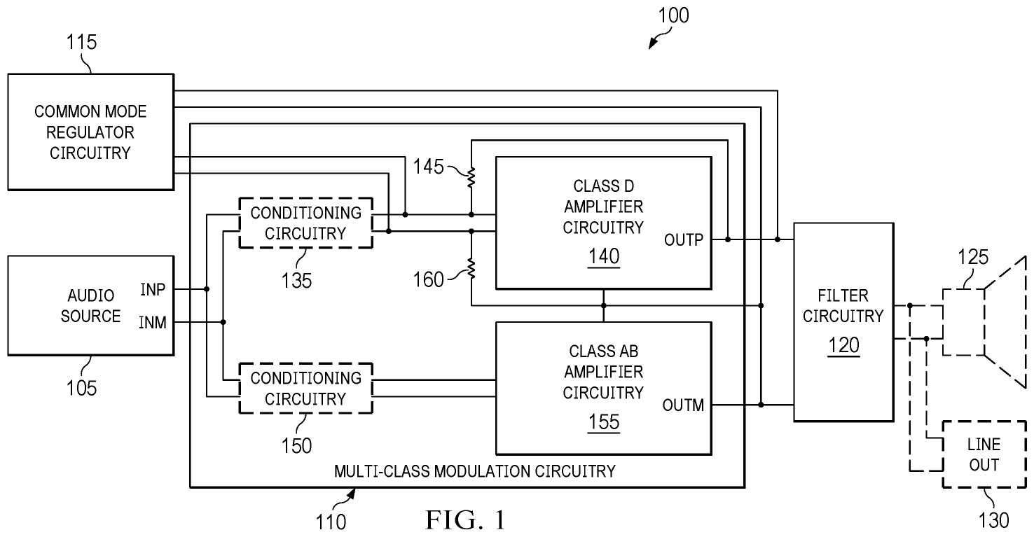

FIG. 1 is a block diagram of an example audio system 100. In the example of FIG. 1, the audio system 100 includes an audio source 105, multi-class modulation circuitry 110, common mode regulator circuitry 115, filter circuitry 120, and may include one or more of a speaker 125 or a line out port 130. The multi-class modulation circuitry 110 of FIG. 1 includes first example conditioning circuitry 135, example class D amplifier circuitry 140, a first example resistor 145, second example conditioning circuitry 150, example class AB amplifier circuitry 155, and a second example resistor 160.

The audio source 105 has a first terminal and a second terminal. The first and second terminals of the audio source 105 are coupled to multi-class modulation circuitry 110. In the example of FIG. 1, the audio source 105 is structured as an analog signal source. In some examples, the audio source 105 is a digital-to-analog converter (DAC). In such examples, the audio source 105 is coupled to digital signal processing circuitry, which supplies digital audio signals.

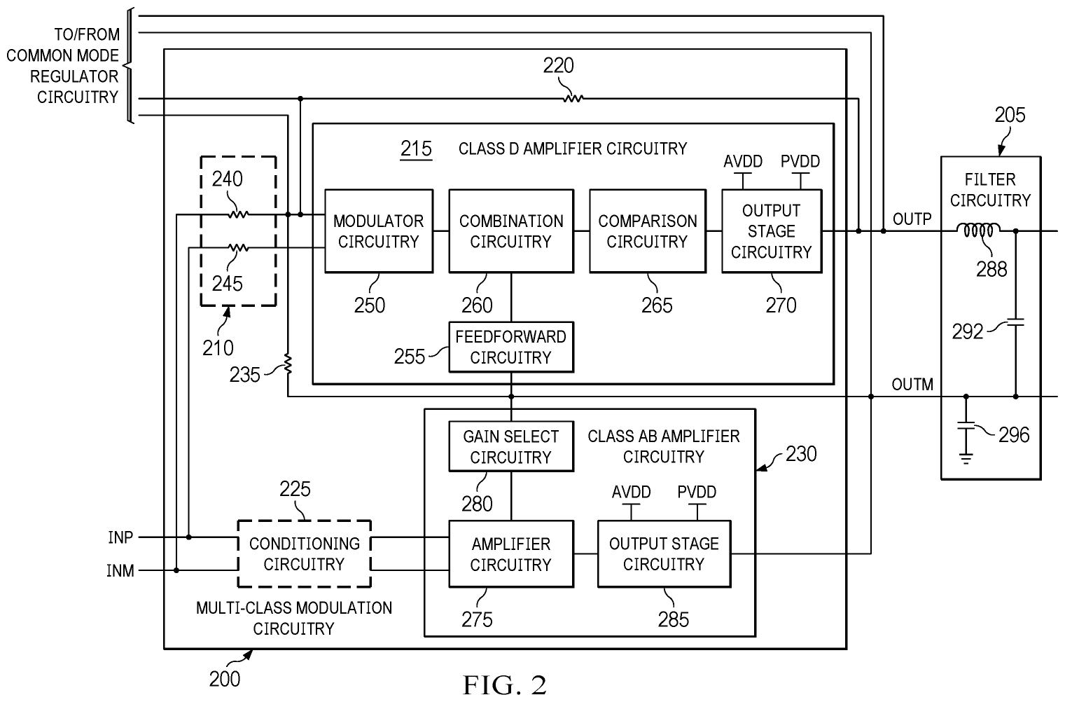

The multi-class modulation circuitry 110 has a first terminal, a second terminal, a third terminal, a fourth terminal, a fifth terminal, and a sixth terminal. The first and second terminals of the multi-class modulation circuitry 110 are coupled to the audio source 105. The third and fourth terminals of the multi-class modulation circuitry 110 are coupled to the common mode regulator circuitry 115. The fifth and sixth terminals of the multi-class modulation circuitry 110 are coupled to the common mode regulator circuitry 115 and the filter circuitry 120. An example of the multi-class modulation circuitry 110 is illustrated and described in connection with FIG. 2, below.

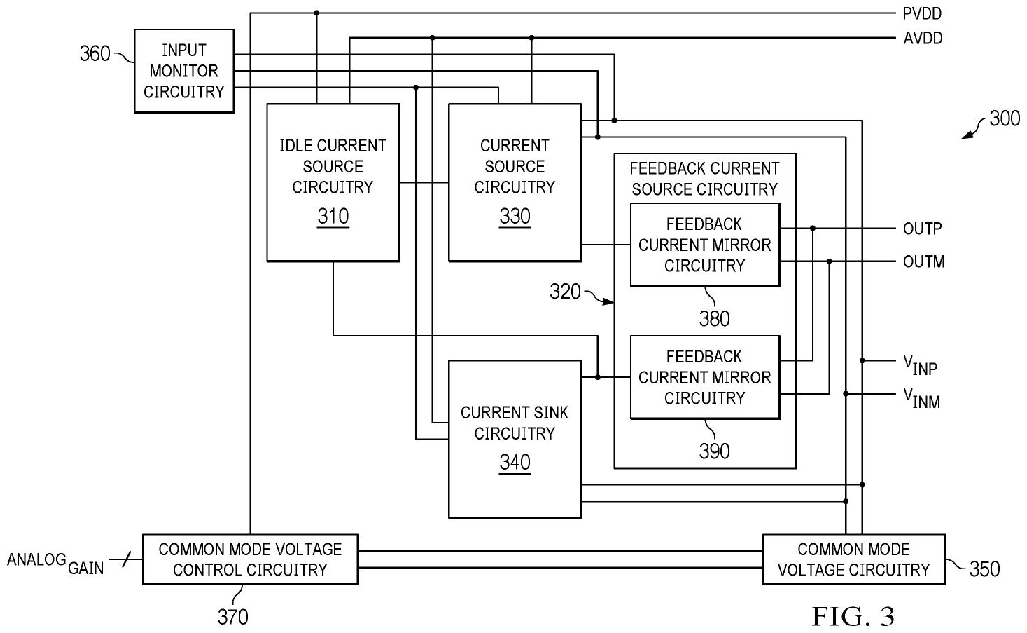

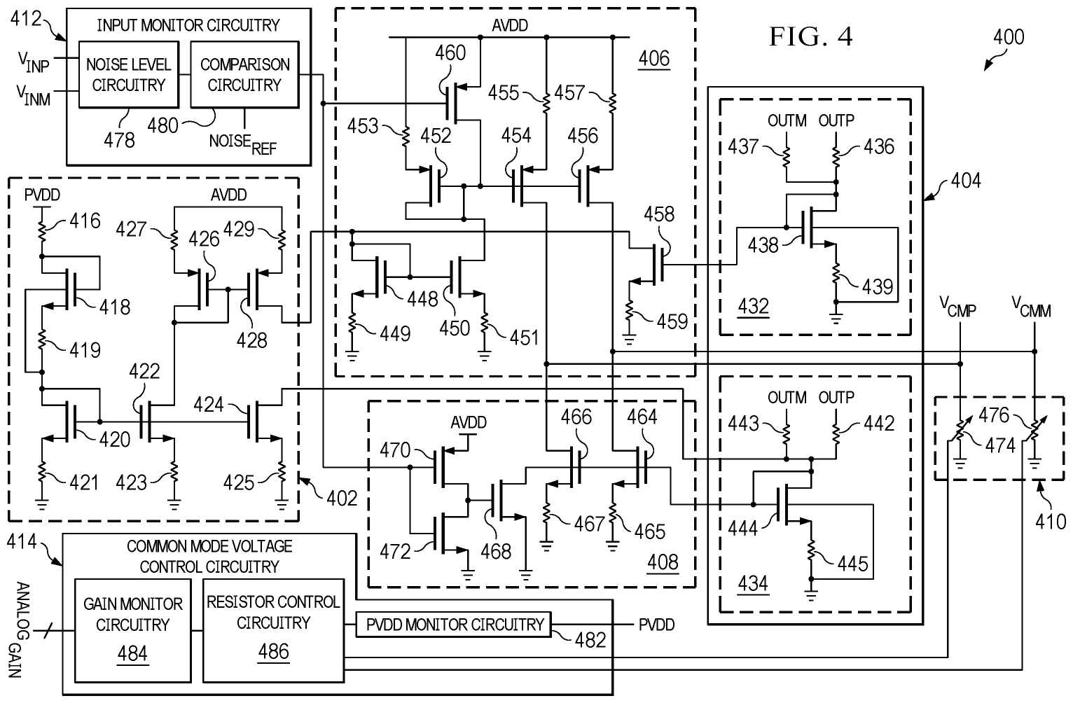

The common mode regulator circuitry 115 has a first terminal, a second terminal, a third terminal, and a fourth terminal. The first and second terminals of the common mode regulator circuitry 115 are coupled to the multi-class modulation circuitry 110. The third and fourth terminals of the common mode regulator circuitry 115 are coupled to the multi-class modulation circuitry 110 and the filter circuitry 120. In some examples, the common mode regulator circuitry 115 further has a fifth terminal and a sixth terminal. In such examples, the fifth terminal of the common mode regulator circuitry 115 is coupled to an input supply terminal, which supplies an input supply voltage (AVDD). The input supply voltage represents a power domain of an input of the multi-class modulation circuitry 110. Also, the sixth terminal of the common mode regulator circuitry 115 is coupled to an output supply terminal, which supplies an output supply voltage (PVDD). The output supply voltage represents a power domain of an output of the multi-class modulation circuitry 110. Examples of the common mode regulator circuitry 115 are illustrated and described in connection with FIGS. 3 and 4, below.

The filter circuitry 120 has a first terminal, a second terminal, a third terminal, and a fourth terminal. The first and second terminals of the filter circuitry 120 are coupled to the multi-class modulation circuitry 110 and the common mode regulator circuitry 115. The third and fourth terminals of the filter circuitry 120 may be coupled to one or more of the speaker 125 or the line out port 130. An example of the filter circuitry 120 is illustrated and described in connection with FIG. 2, below.

The speaker 125 has a first terminal and a second terminal. The first and second terminals of the speaker 125 are coupled to the filter circuitry 120 and may be coupled to the line out port 130. The line out port 130 has a first terminal and a second terminal. The first and second terminals of the line out port 130 are coupled to the filter circuitry 120 and may be coupled to the speaker 125.

The conditioning circuitry 135 has a first terminal, a second terminal, a third terminal, and a fourth terminal. The first and second terminals of the conditioning circuitry 135 are coupled to the audio source 105 and the conditioning circuitry 150. The third terminal of the conditioning circuitry 135 is coupled to the common mode regulator circuitry 115, the class D amplifier circuitry 140, and the resistor 145. The fourth terminal of the conditioning circuitry 135 is coupled to the common mode regulator circuitry 115, the class D amplifier circuitry 140, and the resistor 160. An example of the conditioning circuitry 135 is illustrated and described in connection with FIG. 2, below.

The class D amplifier circuitry 140 has a first terminal, a second terminal, a third terminal, and a fourth terminal. The first terminal of the class D amplifier circuitry 140 is coupled to the common mode regulator circuitry 115, the conditioning circuitry 135, and the resistor 145. The second terminal of the class D amplifier circuitry 140 is coupled to the common mode regulator circuitry 115, the conditioning circuitry 135, and the resistor 160. The third terminal of the class D amplifier circuitry 140 is coupled to the common mode regulator circuitry 115, the filter circuitry 120, and the resistor 145. The fourth terminal of the class D amplifier circuitry 140 is coupled to the common mode regulator circuitry 115, the filter circuitry 120, the class AB amplifier circuitry 155, and the resistor 160. An example of the class D amplifier circuitry 140 is illustrated and described in connection with FIG. 2, below.

The resistor 145 has a first terminal and a second terminal. The first terminal of the resistor 145 is coupled to the common mode regulator circuitry 115, the conditioning circuitry 135, and the class D amplifier circuitry 140. The second terminal of the resistor 145 is coupled to the common mode regulator circuitry 115, the filter circuitry 120, and the class D amplifier circuitry 140. In some examples, the resistor 145 is referred to as a feedback resistor (R_{fb}).

The conditioning circuitry 150 has a first terminal, a second terminal, a third terminal, and a fourth terminal. The first and second terminals of the conditioning circuitry 150 are coupled to the audio source 105 and the conditioning circuitry 135. The third and fourth terminals of the conditioning circuitry 150 are coupled to the class AB amplifier circuitry 155. An example of the conditioning circuitry 150 is illustrated and described in connection with FIG. 2, below.

The class AB amplifier circuitry 155 has a first terminal, a second terminal, a third terminal, and a fourth terminal. The first and second terminals of the class AB amplifier circuitry 155 are coupled to the conditioning circuitry 150. The third and fourth terminals of the class AB amplifier circuitry 155 are coupled to the common mode regulator circuitry 115, the filter circuitry 120, the class D amplifier circuitry 140, and the resistor 160. An example of the class AB amplifier circuitry 155 is illustrated and described in connection with FIG. 2, below.

The resistor 160 has a first terminal and a second terminal. The first terminal of the resistor 160 is coupled to the common mode regulator circuitry 115, the conditioning circuitry 135, and the class D amplifier circuitry 140. The second terminal of the resistor 160 is coupled to the common mode regulator circuitry 115, the filter circuitry 120, the class D amplifier circuitry 140, and the class AB amplifier circuitry 155. In some examples, the resistor 145 is referred to as a feedback resistor (R_{fb}).

In example operation, the audio source 105 supplies a differential pair of input signals to multi-class modulation circuitry 110. In the example of FIG. 1, the differential pair of input signals represent an audio signal that, when supplied to the speaker 125, corresponds to audible sound. In some examples, the conditioning circuitry 135, 150 filter the differential pair of input signals to reduce noise. The class D amplifier circuitry 140 receives a differential pair of amplifier input signals including a plus side amplifier input signal and a minus side amplifier input signal. The plus side amplifier input signal of the class D amplifier circuitry 140 includes contributions from a plus side of the differential pair of input signals, feedback currents from the resistor 145, and currents from the common mode regulator circuitry 115. The minus side amplifier input signal of the class D amplifier circuitry 140 includes contributions from a minus side of the differential pair of input signals, feedback currents from the resistor 160, and currents from the common mode regulator circuitry 115. The class D amplifier circuitry 140 modulates the differential pair of amplifier input signals to generate a plus side output signal (OUTP). The class AB amplifier circuitry 155 modulates the filtered differential pair of signals to generate a minus side output signal (OUTM). The filter circuitry 120 supplies an amplified audio signal to the speaker 125 and the line out port 130 by filtering the plus and minus side output signals.

In such example operations, the resistors 145, 160 form feedback paths between the plus and minus side inputs of the class D amplifier circuitry 140 and the plus and minus side output signals of the multi-class modulation circuitry 110. The feedback currents through the resistors 145, 160 are proportional to the differences between voltages of the plus and minus side inputs and the plus and minus side outputs. The common mode regulator circuitry 115 replicates the feedback currents through the resistors 145, 160. The common mode regulator circuitry 115 compares the feedback currents to an idle current, which represents the feedback currents during idle operations. When the idle current is greater than the feedback currents, the common mode regulator circuitry 115 supplies a current equal to the idle current minus the feedback currents to the inputs of the class D amplifier circuitry 140. When the feedback currents are greater than the idle current, the common mode regulator circuitry 115 sinks a current equal to the feedback currents minus the idle current from the inputs of the class D amplifier circuitry 140. Advantageously, the common mode regulator circuitry 115 reduces variations in the common mode of the inputs of the class D amplifier circuitry 140 by sourcing and sinking currents from inputs of the class D amplifier circuitry 140.

FIG. 2 is a block diagram of example multi-class modulation circuitry 200, which is an example of the multi-class modulation circuitry 110 of FIG. 1, and example filter circuitry 205, which is an example of the filter circuitry 120 of FIG. 1. The multi-class modulation circuitry 200 of FIG. 2 includes first example conditioning circuitry 210, example class D amplifier circuitry 215, a first example resistor 220, second example conditioning circuitry 225, example class AB amplifier circuitry 230, and a second example resistor 235. The conditioning circuitry 210 of FIG. 2 includes a third example resistor 240 and a fourth example resistor 245. The class D amplifier circuitry 215 of FIG. 2 includes example modulator circuitry 250, example feedforward circuitry 255, example combination circuitry 260, example comparison circuitry 265, and example output stage circuitry 270. The class AB amplifier circuitry 230 of FIG. 2 includes example amplifier circuitry 275, example gain select circuitry 280, and example output stage circuitry 285. The filter circuitry 205 of FIG. 2 includes an example inductor 288, a first example capacitor 292, and a second example capacitor 296. The multi-class modulation circuitry 200 of FIG. 2 is structured to implement single inductor (1L) modulation. Examples of the amplifier circuitry 215, 230 are further illustrated and described in “METHODS AND APPARATUS TO MODULATE SIGNALS USING MULTI-CLASS MODULATION CIRCUITRY” U.S. patent application Ser. No. 18/385,848, which is incorporated by reference in its entirety and is assigned to the assignee of the instant application.

The conditioning circuitry 210 is coupled to the resistors 220, 235, the class D amplifier circuitry 215, and may be coupled to the audio source 105 of FIG. 1 and the common mode regulator circuitry 115 of FIG. 1. The conditioning circuitry 210 is an example of the conditioning circuitry 135 of FIG. 1. The class D amplifier circuitry 215 is coupled to the conditioning circuitry 210, the resistors 220, 235, the filter circuitry 205, the class AB amplifier circuitry 230, and may be coupled to the common mode regulator circuitry 115. The class D amplifier circuitry 215 is an example of the class D amplifier circuitry 140 of FIG. 1. The resistor 220 is coupled to the filter circuitry 205, the conditioning circuitry 210, the class D amplifier circuitry 215, and may be coupled to the common mode regulator circuitry 115. The resistor 220 is an example of the resistor 145 of FIG. 1. The conditioning circuitry 225 is coupled to the conditioning circuitry 210, the class AB amplifier circuitry 230, and may be coupled to the audio source 105. The conditioning circuitry 225 is an example of the conditioning circuitry 150 of FIG. 1. The class AB amplifier circuitry 230 is coupled to the filter circuitry 205, the class D amplifier circuitry 215, the conditioning circuitry 225, the resistor 235, and may be coupled to the common mode regulator circuitry 115. The class AB amplifier circuitry 230 is an example of the class AB amplifier circuitry 155 of FIG. 1. The resistor 235 is coupled to the filter circuitry 205, the conditioning circuitry 210, the class D amplifier circuitry 215, the class AB amplifier circuitry 230, and may be coupled to the common mode regulator circuitry 115. The resistor 235 is an example of the resistor 160 of FIG. 1.

The resistor 240 has a first terminal and a second terminal. The first terminal of the resistor 240 is coupled to the conditioning circuitry 225 and may be coupled to the audio source 105. The second terminal of the resistor 240 is coupled to the class D amplifier circuitry 215, the resistor 220, and may be coupled to the common mode regulator circuitry 115. The resistor 245 has a first terminal and a second terminal. The first terminal of the resistor 245 is coupled to the conditioning circuitry 225 and may be coupled to the audio source 105. The second terminal of the resistor 245 is coupled to the class D amplifier circuitry 215, the resistor 235, and may be coupled to the common mode regulator circuitry 115. Similar to the resistors 240, 245 being structured to form the conditioning circuitry 210, the conditioning circuitry 225 may have a similar structure (e.g., structured from similar instances of the resistors 240, 245).

The modulator circuitry 250 has a first terminal, a second terminal, and a third terminal. The first terminal of the modulator circuitry 250 is coupled to the conditioning circuitry 210, the resistor 220, and may be coupled to the common mode regulator circuitry 115. The second terminal of the modulator circuitry 250 is coupled to the conditioning circuitry 210, the resistor 235, and may be coupled to the common mode regulator circuitry 115. The third terminal of the modulator circuitry 250 is coupled to the combination circuitry 260. In some examples, the modulator circuitry 250 has a plurality of terminals coupled to the combination circuitry 260. For example, when the modulator circuitry 250 is a multi-order modulator, the modulator circuitry 250 is structured to have a plurality of terminals coupled to the combination circuitry 260. In the example of FIG. 2, the modulator circuitry 250 is structured as integrator circuitry. In some examples, the modulator circuitry 250 is multi-order integrator circuitry.

The feedforward circuitry 255 has a first terminal and a second terminal. The first terminal of the feedforward circuitry 255 is coupled to the filter circuitry 205, the class AB amplifier circuitry 230, the resistor 235, and may be coupled to the common mode regulator circuitry 115. The second terminal of the feedforward circuitry 255 is coupled to the combination circuitry 260.

The combination circuitry 260 has a first terminal, a second terminal, and a third terminal. The first terminal of the combination circuitry 260 is coupled to the modulator circuitry 250. The second terminal of the combination circuitry 260 is coupled to the feedforward circuitry 255. The third terminal of the combination circuitry 260 is coupled to the comparison circuitry 265. In some examples, the combination circuitry 260 has a plurality of terminals coupled to the modulator circuitry 250 or the feedforward circuitry 255.

The comparison circuitry 265 has a first terminal and a second terminal. The first terminal of the comparison circuitry 265 is coupled to the combination circuitry 260. The second terminal of the comparison circuitry 265 is coupled to the output stage circuitry 270.

The output stage circuitry 270 has a first terminal, a second terminal, a third terminal, and a fourth terminal. The first terminal of the output stage circuitry 270 is coupled to the comparison circuitry 265. The second terminal of the output stage circuitry 270 is coupled to the filter circuitry 205, the resistor 220, and may be coupled to the common mode voltage circuitry 115. The third terminal of the output stage circuitry 270 is coupled to an input supply terminal, which supplies an input supply voltage (AVDD). In some examples, one or more components of the class D amplifier circuitry 215 are also coupled to the input supply terminal. The fourth terminal of the output stage circuitry 270 is coupled to an output supply terminal, which supplies an output supply voltage (PVDD). In some examples, the feedforward circuitry 255 is also coupled to the output supply terminal.

The amplifier circuitry 275 has a first terminal, a second terminal, a third terminal, and a fourth terminal. The first and second terminals of the amplifier circuitry 275 are coupled to the conditioning circuitry 225. The third terminal of the amplifier circuitry 275 is coupled to the gain select circuitry 280. The fourth terminal of the amplifier circuitry 275 is coupled to the output stage circuitry 285.

The gain select circuitry 280 has a first terminal and a second terminal. The first terminal of the gain select circuitry 280 is coupled to the filter circuitry 205, the class D amplifier circuitry 215, the resistor 235, the output stage circuitry 285, and may be coupled to the common mode regulator circuitry 115. The second terminal of the gain select circuitry 280 is coupled to the amplifier circuitry 275.

The output stage circuitry 285 has a first terminal, a second terminal, a third terminal, and a fourth terminal. The first terminal of the output stage circuitry 285 is coupled to the amplifier circuitry 275. The second terminal of the output stage circuitry 285 is coupled to the filter circuitry 205, the class D amplifier circuitry 215, the resistor 235, the gain select circuitry 280, and may be coupled to the common mode regulator circuitry 115. The third terminal of the output stage circuitry 285 is coupled to the input supply terminal, which supplies the input supply voltage. The fourth terminal of the output stage circuitry 285 is coupled to the output supply terminal, which supplies the output supply voltage.

The inductor 288 has a first terminal and a second terminal. The first terminal of the inductor 288 is coupled to the multi-class modulation circuitry 200 and may be coupled to the common mode regulator circuitry 115. The second terminal of the inductor 288 is coupled to the capacitor 292 and may be coupled to one or more of the speaker 125 of FIG. 1 or the line out port 130 of FIG. 1.

The capacitor 292 has a first terminal and a second terminal. The first terminal of the capacitor 292 is coupled to the inductor 288 and may be coupled to one or more of the speaker 125 or the line out port 130. The second terminal of the capacitor 292 is coupled to the multi-class modulation circuitry 200, the capacitor 296, and may be coupled to the common mode regulator circuitry 115 and one or more of the speaker 125 or the line out port 130.

The capacitor 296 has a first terminal and a second terminal. The first terminal of the capacitor 296 is coupled to the multi-class modulation circuitry 200, the capacitor 292, and may be coupled to the common mode regulator circuitry 115 and one or more of the speaker 125 or the line out port 130. The second terminal of the capacitor 296 is coupled to a common terminal, which supplies a common potential (e.g., ground). In some examples, one or more components of FIG. 2 are coupled to the common terminal, which supplies the common potential.

In example operation, the conditioning circuitry 210, 225 receives a differential pair of input signals including a plus side input signal (INP) and a minus side input signal (INM). The conditioning circuitry 210, 225 supplies the differential pair of input signals to the class D amplifier circuitry 215 and the class AB amplifier circuitry 230. In some examples, the conditioning circuitry 210, 225 filter the differential pair of input signals to reduce noise. In other examples, such as the conditioning circuitry 210, the conditioning circuitry 210, 225 include summation resistors (e.g., the resistors 240, 245) to allows signals to construct at inputs of the class D amplifier circuitry 215 and the class AB amplifier circuitry 230. For example, currents from the common mode regulator circuitry 115 combine with currents from the differential pair of input signals at inputs of the class D amplifier circuitry 215. In such example operations, the class D amplifier circuitry 215 receives a differential pair of amplifier input signals, which include contributions from the differential pair of input signals from the conditioning circuitry 210, the currents from the common mode regulator circuitry 115, and currents from the feedback current paths through the resistors 220, 235. Advantageously, the common mode regulator circuitry 115 may regulate the common mode voltage of the differential pair of amplifier input signals by adjusting current contributions at the inputs of the class D amplifier circuitry 215.

In example operations of the class D amplifier circuitry 215, the modulator circuitry 250 receives the differential pair of amplifier input signals. The modulator circuitry 250 integrates the differential pair of amplifier input signals. The modulator circuitry 250 combines contributions from one or more orders of integrals to generate a modulated signal that represents the differential pair of amplifier input signals. The feedforward circuitry 255 amplifies a minus side output signal (OUTM) from the class AB amplifier circuitry 230 by a gain to step down the signal strength of the minus side output signal from the output supply voltage to an input supply voltage. The combination circuitry 260 adjusts the modulated signal from the modulator circuitry 250 to account for linearities of the output supply voltage using the stepped down output supply voltage from the feedforward circuitry 255. The comparison circuitry 265 generates a square waveform having an adjustable duty cycle by comparing the adjusted modulated signal to a triangular waveform. The duty cycle of the square waveform represents the amplitudes of the adjusted modulated signal. The output stage circuitry 270 generates a plus side output signal (OUTP) by stepping up the square waveform from the input supply voltage to the output supply voltage. Advantageously, the plus side output signal has a varying duty cycle that represents amplitudes of the differential pair of amplifier input signals.

In example operations of the class AB amplifier circuitry 230, the amplifier circuitry 275 receives the differential pair of input signals from the conditioning circuitry 225. The gain select circuitry 280 sets a gain of the amplifier circuitry 275 responsive to the minus side output signal. The gain select circuitry 280 saturates the output of the amplifier circuitry 275 by setting the gain of the amplifier circuitry 275 to a relatively high value. The amplifier circuitry 275 amplifies the differential pair of input signals by the gain from the gain select circuitry 280. In such example operations, the output of the amplifier circuitry 275 is saturated between supply voltages of the amplifier circuitry 275. However, despite a relatively high gain from the gain select circuitry 280, relatively small amplitudes of the differential pair of input signals result in the output of the amplifier circuitry 275 being linear during transitions between supply voltages. The output stage circuitry 285 generates the minus side output signal by stepping up the output of the amplifier circuitry 275 from the input supply voltage to the output supply voltage. Advantageously, the class D amplifier circuitry 215 compensates the plus side output signal to account for non-ideal linear portions of the minus side output signal responsive to the feedforward circuitry 255.

In example operations of the filter circuitry 205, the inductor 288 receives the plus side output signal from the class D amplifier circuitry 215. The inductor 288 averages relatively high-speed changes in the currents of the plus side output signal. For example, the inductor 288 and capacitor 292 generate a sinusoidal waveform by averaging currents of the varying duty cycles of the square waveform. The capacitor 296 receives the minus side output signal from the class AB amplifier circuitry 230. The capacitor 296 reduces noise of the minus side output signal. The capacitor 292 is a coupling capacitor that reduces noise between the filtered output signals. Advantageously, the filter circuitry 205 generates a differential pair of output signals that represent a relatively higher power version of the differential pair of input signals.

FIG. 3 is a block diagram of example common mode regulator circuitry 300, which is an example of the common mode regulator circuitry 115 of FIG. 1. In the example of FIG. 3, the common mode regulator circuitry 300 includes idle current source circuitry 310, feedback current source circuitry 320, current source circuitry 330, current sink circuitry 340, common mode voltage circuitry 350, input monitor circuitry 360, and common mode voltage control circuitry 370. The feedback current source circuitry 320 of FIG. 3 includes first example feedback current mirror circuitry 380 and second example feedback current mirror circuitry 390.

The idle current source circuitry 310 has a first terminal, a second terminal, a third terminal, and a fourth terminal. The first terminal of the idle current source circuitry 310 is coupled to the input supply terminal, which supplies the input supply voltage (AVDD). The second terminal of the idle current source circuitry 310 is coupled to the output supply terminal, which supplies the output supply voltage (PVDD). The third terminal of the idle current source circuitry 310 is coupled to the current source circuitry 330. The fourth terminal of the idle current source circuitry 310 is coupled to the feedback current source circuitry 320 and the current sink circuitry 340.

The feedback current source circuitry 320 has a first terminal, a second terminal, a third terminal, a fourth terminal, and a fifth terminal. The first terminal of the feedback current source circuitry 320 is coupled to a plus side output terminal, which supplies a plus side output signal (OUTP). In some examples, the plus side output terminal couples the filter circuitry 120 of FIG. 1, the class D amplifier circuitry 140 of FIG. 1, and the resistor 145 of FIG. 1. In other examples, the plus side input terminal couples the filter circuitry 205 of FIG. 2, the class D amplifier circuitry 215 of FIG. 2, and the resistor 220 of FIG. 2. The second terminal of the feedback current source circuitry 320 is coupled to a minus side output terminal, which supplies a minus side output signal (OUTM). In some examples, the minus side output terminal couples the filter circuitry 120 of FIG. 1, the class AB amplifier circuitry 155 of FIG. 1, and the resistor 160 of FIG. 1. In other examples, the minus side input terminal couples the filter circuitry 205 of FIG. 2, the class AB amplifier circuitry 230 of FIG. 2, and the resistor 235 of FIG. 2. The third terminal of the feedback current source circuitry 320 is coupled to the current source circuitry 330. The fourth terminal of the feedback current source circuitry 320 is coupled to the idle current source circuitry 310 and the current sink circuitry 340. The fifth terminal of the feedback current source circuitry 320 is coupled to the current sink circuitry 340.

The current source circuitry 330 has a first terminal, a second terminal, a third terminal, a fourth terminal, and a fifth terminal. The first terminal of the current source circuitry 330 is coupled to the input supply terminal, which supplies the input supply voltage. The second terminal of the current source circuitry 330 is coupled to the idle current source circuitry 310. The third terminal of the current source circuitry 330 is coupled to the current sink circuitry 340 and the input monitor circuitry 360. The fourth terminal of the current source circuitry 330 is coupled to a plus side input terminal, which supplies a plus side input signal (IMP). In some examples, the plus side input terminal couples the conditioning circuitry 135 of FIG. 1, the class D amplifier circuitry 140 of FIG. 1, and the resistor 145 of FIG. 1. In other examples, the plus side input terminal couples the conditioning circuitry 210 of FIG. 2, the class D amplifier circuitry 215 of FIG. 2, and the resistor 220 of FIG. 2. The fifth terminal of the current source circuitry 330 is coupled to a minus side input terminal, which supplies a minus side input signal (IMM). In some examples, the minus side input terminal couples the conditioning circuitry 135 of FIG. 1, the class D amplifier circuitry 140 of FIG. 1, and the resistor 160 of FIG. 1. In other examples, the minus side input terminal couples the conditioning circuitry 210 of FIG. 2, the class D amplifier circuitry 215 of FIG. 2, and the resistor 235 of FIG. 2.

The current sink circuitry 340 has a first terminal, a second terminal, a third terminal, a fourth terminal, and a fifth terminal. The first terminal of the current sink circuitry 340 is coupled to the input supply terminal, which supplies the input supply voltage. The second terminal of the current sink circuitry 340 is coupled to the idle current source circuitry 310 and the feedback current source circuitry 320. The third terminal of the current sink circuitry 340 is coupled to the current source circuitry 330 and the input monitor circuitry 360. The fourth terminal of the current sink circuitry 340 is coupled to the plus side input terminal, which supplies the plus side input signal. The fifth terminal of the current sink circuitry 340 is coupled to the minus side input terminal, which supplies the minus side input signal.

The common mode voltage circuitry 350 has a first terminal, a second terminal, a third terminal, and a fourth terminal. The first terminal of the common mode voltage circuitry 350 is coupled to the plus side input terminal, which supplies the plus side input signal. The second terminal of the common mode voltage circuitry 350 is coupled to the minus side input terminal, which supplies the minus side input signal. The third and fourth terminals of the common mode voltage circuitry 350 are coupled to the common mode voltage control circuitry 370. In some examples, the common mode voltage circuitry 350 has any number of terminals coupled to the common mode voltage control circuitry 370.

The input monitor circuitry 360 has a first terminal, a second terminal, and a third terminal. The first terminal of the input monitor circuitry 360 is coupled to the plus side input terminal, which supplies the plus side input signal. The second terminal of the input monitor circuitry 360 is coupled to the minus side input terminal, which supplies the minus side input signal. The third terminal of the input monitor circuitry 360 is coupled to the current source circuitry 330 and the current sink circuitry 340.

The common mode voltage control circuitry 370 has a first terminal, a second terminal, a third terminal, and a fourth terminal. The first terminal of the common mode voltage control circuitry 370 is coupled to the output supply terminal, which supplies the output supply voltage. The second and third terminals of the common mode voltage control circuitry 370 are coupled to the common mode voltage circuitry 350. The fourth terminal of the common mode voltage control circuitry 370 is coupled to an analog gain terminal, which supplies an indication of the analog gain of the class D amplifier circuitry 140, 215. In some examples, the common mode voltage control circuitry 370 is coupled to a BUS, which supplies the analog gain. In other examples, the common mode voltage control circuitry 370 is coupled to a register, which sets the analog gain.

The feedback current mirror circuitry 380 has a first terminal, a second terminal, and a third terminal. The first terminal of the feedback current mirror circuitry 380 is coupled to the plus side output terminal, which supplies the plus side output signal. The second terminal of the feedback current mirror circuitry 380 is coupled to the minus side output terminal, which supplies the minus side output signal. The third terminal of the feedback current mirror circuitry 380 is coupled to the current source circuitry 330.

The feedback current mirror circuitry 390 has a first terminal, a second terminal, and a third terminal. The first terminal of the feedback current mirror circuitry 390 is coupled to the plus side output terminal, which supplies the plus side output signal. The second terminal of the feedback current mirror circuitry 390 is coupled to the minus side output terminal, which supplies the minus side output signal. The third terminal of the feedback current mirror circuitry 390 is coupled to the idle current source circuitry 310 and the current sink circuitry 340.

FIG. 4 is a schematic diagram of example common mode regulator circuitry 400, which is an example of the common mode regulator circuitry 115 and 300 of FIGS. 1 and 3. In the example of FIG. 4, the common mode regulator circuitry 400 includes idle current source circuitry 402, feedback current source circuitry 404, current source circuitry 406, current sink circuitry 408, common mode voltage circuitry 410, input monitor circuitry 412, and common mode voltage control circuitry 414. The idle current source circuitry 402 of FIG. 4 includes a first example resistor 416, a first example transistor 418, a second example resistor 419, a second example transistor 420, a third example resistor 421, a third example transistor 422, a fourth example resistor 423, a fourth example transistor 424, a fifth example resistor 425, a fifth example transistor 426, a sixth example resistor 427, a sixth example transistor 428, and a seventh example resistor 429.

The feedback current source circuitry 404 of FIG. 4 includes first example feedback current mirror circuitry 432 and second example feedback current mirror circuitry 434. The feedback current mirror circuitry 432 of FIG. 4 includes a first example resistor 436, a second example resistor 437, an example transistor 438, and a third example resistor 439. The feedback current mirror circuitry 434 of FIG. 4 includes a first example resistor 442, a second example resistor 443, an example transistor 444, and a third example resistor 445. The current source circuitry 406 of FIG. 4 includes a first example transistor 448, a first example resistor 449, a second example transistor 450, a second example resistor 451, a third example transistor 452, a third example resistor 453, a fourth example transistor 454, a fourth example resistor 455, a fifth example transistor 456, a fifth example resistor 457, a sixth example transistor 458, a sixth example resistor 459, and a seventh example transistor 460.

The current sink circuitry 408 of FIG. 4 includes a first example transistor 464, a first example resistor 465, a second example transistor 466, a second example resistor 467, a third example transistor 468, a fourth example transistor 470, and a fifth example transistor 472. The common mode voltage circuitry 410 of FIG. 4 includes a first example resistor 474 and a second example resistor 476. The input monitor circuitry 412 of FIG. 4 includes example noise level circuitry 478 and example comparison circuitry 480. The common mode voltage control circuitry 414 of FIG. 4 includes example supply monitor circuitry 482, example gain monitor circuitry 484, and example resistor control circuitry 486.

The idle current source circuitry 402 is coupled to the feedback current source circuitry 404, the current source circuitry 406, the current sink circuitry 408, the input supply terminal, which supplies the input supply voltage, and the output supply terminal, which supplies the output supply voltage. The idle current source circuitry 402 is an example of the idle current source circuitry 310 of FIG. 3.

The feedback current source circuitry 404 is coupled to the idle current source circuitry 402, the current source circuitry 406, the current sink circuitry 408, and the plus and minus side output terminals, which supply the plus and minus side output signals. The feedback current source circuitry 404 is an example of the feedback current source circuitry 320 of FIG. 3.

The current source circuitry 406 is coupled to the idle current source circuitry 402, the feedback current source circuitry 404, the current sink circuitry 408, the common mode voltage circuitry 410, the input monitor circuitry 412, the input supply terminal, which supplies the input supply voltage, and the plus and minus side input terminals, which supply the plus and minus common mode voltages. The current source circuitry 406 is an example of the current source circuitry 330 of FIG. 3.

The current sink circuitry 408 is coupled to the idle current source circuitry 402, the feedback current source circuitry 404, the current source circuitry 406, the common mode voltage circuitry 410, the input monitor circuitry 412, the input supply terminal, which supplies the input supply voltage, and the plus and minus side input terminals, which supply the plus and minus side input signals. The current sink circuitry 408 is an example of the current sink circuitry 340 of FIG. 3.

The common mode voltage circuitry 410 is coupled to the current source circuitry 406, the current sink circuitry 408, and the plus and minus side input terminals, which supply the plus and minus side input signals. The common mode voltage circuitry 410 is an example of the common mode voltage circuitry 350 of FIG. 3.

The input monitor circuitry 412 is coupled to the current source circuitry 406, the current sink circuitry 408, and the plus and minus side input terminals, which supply the plus and minus side input signals. The input monitor circuitry 412 is an example of the input monitor circuitry 360 of FIG. 3.

The common mode voltage control circuitry 414 is coupled to the common mode voltage circuitry 410, the output supply terminal, which supplies the output supply voltage, and the analog gain terminal, which supplies the indication of the analog gain. The common mode voltage control circuitry 414 is an example of the common mode voltage circuitry 370 of FIG. 3.

The resistor 416 has a first terminal and a second terminal. The first terminal of the resistor 416 is coupled to the output supply terminal, which supplies the output supply voltage. The second terminal of the resistor 416 is coupled to the transistor 418. In the example of FIG. 4, the resistor 416 has a resistance that is equal to the resistance of the resistors 220, 235 of FIG. 2.

The transistor 418 has a first terminal, a second terminal, a third terminal, and a control terminal. The first and control terminals of the transistor 418 are coupled to the resistor 416. The second terminal of the transistor 418 is coupled to the resistor 419. The third terminal of the transistor 418, which may be referred to as a bulk terminal, is coupled to the resistor 419 and the transistors 420, 422, 424. The resistor 419 has a first terminal and a second terminal. The first terminal of the resistor 419 is coupled to the transistor 418. The second terminal of the resistor 419 is coupled to the transistors 418, 420, 422, 424.

The transistor 420 has a first terminal, a second terminal, and a control terminal. The first and control terminals of the transistor 420 are coupled to the transistors 418, 422, 424 and the resistor 419. The second terminal of the transistor 420 is coupled to the resistor 421. The resistor 421 has a first terminal and a second terminal. The first terminal of the resistor 421 is coupled to the transistor 420. The second terminal of the resistor 421 is coupled to a common terminal, which supplies a common potential (e.g., ground).

The transistor 422 has a first terminal, a second terminal, and a control terminal. The first terminal of the transistor is coupled to the transistors 426, 428. The second terminal of the transistor 422 is coupled to the resistor 423. The control terminal of the transistor 422 is coupled to the transistors 418, 420, 424 and the resistor 419. The resistor 423 has a first terminal and a second terminal. The first terminal of the resistor 423 is coupled to the transistor 422. The second terminal of the resistor 423 is coupled to the common terminal, which supplies the common potential.

The transistor 424 has a first terminal, a second terminal, and a control terminal. The first terminal of the transistor 424 is coupled to the feedback current source circuitry 404 and the current sink circuitry 408. The second terminal of the transistor 424 is coupled to the resistor 425. The control terminal of the transistor 424 is coupled to the transistors 418, 420, 422 and the resistor 419. The resistor 425 has a first terminal and a second terminal. The first terminal of the resistor 425 is coupled to the transistor 424. The second terminal of the resistor 425 is coupled to the common terminal, which supplies the common potential.

The transistor 426 has a first terminal, a second terminal, and a control terminal. The first terminal of the transistor 426 is coupled to the resistor 427. The second and control terminals of the transistor 426 are coupled to the transistors 422, 428. The resistor 427 has a first terminal and a second terminal. The first terminal of the resistor 427 is coupled to the input supply terminal, which supplies the input supply voltage. The second terminal of the resistor 427 is coupled to the transistor 426.

The transistor 428 has a first terminal, a second terminal, and a control terminal. The first terminal of the transistor 428 is coupled to the resistor 429. The second terminal of the transistor 428 is coupled to the current source circuitry 406. The control terminal of the transistor 428 is coupled to the transistors 422, 426. The resistor 429 has a first terminal and a second terminal. The first terminal of the resistor 429 is coupled to the input supply terminal, which supplies the input supply voltage. The second terminal of the resistor 429 is coupled to the transistor 428.

The feedback current mirror circuitry 432 is coupled to the current source circuitry 406 and the plus and minus side output terminals, which supply the plus and minus side output signals. The feedback current mirror circuitry 432 is an example of the feedback current mirror circuitry 380 of FIG. 3.

The feedback current mirror circuitry 434 is coupled to the idle current source circuitry 402, the current sink circuitry 408, and the plus and minus side output terminals, which supply the plus and minus side output signals. The feedback current mirror circuitry 434 is an example of the feedback current mirror circuitry 390 of FIG. 3.

The resistor 436 has a first terminal and a second terminal. The first terminal of the resistor 436 is coupled to the plus side output terminal, which supplies the plus side output signal. The second terminal of the resistor 436 is coupled to the current source circuitry 406, the resistor 437, and the transistor 438. The resistor 437 has a first terminal and a second terminal. The first terminal of the resistor 437 is coupled to the minus side output terminal, which supplies the minus side output signal. The second terminal of the resistor 437 is coupled to the current source circuitry 406, the resistor 436, and the transistor 438.

The transistor 438 has a first terminal, a second terminal, a third terminal, and a control terminal. The first and control terminals of the transistor 438 are coupled to the current source circuitry 406 and the resistors 436, 437. The second terminal of the transistor 438 is coupled to the resistor 439. The third terminal of the transistor 438, which may be referred to as a bulk terminal, is coupled to the common terminal, which supplies the common potential. The resistor 439 has a first terminal and a second terminal. The first terminal of the resistor 439 is coupled to the transistor 438. The second terminal of the resistor 439 is coupled to the common terminal, which supplies the common potential.

The resistor 442 has a first terminal and a second terminal. The first terminal of the resistor 442 is coupled to the plus side output terminal, which supplies the plus side output signal. The second terminal of the resistor 442 is coupled to the idle current source circuitry 402, the current sink circuitry 408, the resistor 443, and the transistor 444. The resistor 443 has a first terminal and a second terminal. The first terminal of the resistor 443 is coupled to the minus side output terminal, which supplies the minus side output signal. The second terminal of the resistor 443 is coupled to the idle current source circuitry 402, the current sink circuitry 408, the resistor 443, and the transistor 444.

The transistor 444 has a first terminal, a second terminal, and a control terminal. The first and control terminals of the transistor 444 are coupled to the idle current source circuitry 402, the current sink circuitry 408, and the resistors 442, 443. The second terminal of the transistor 444 is coupled to the resistor 445. The third terminal of the transistor 444, which may be referred to as a bulk terminal, is coupled to the common terminal, which supplies the common potential. The resistor 445 has a first terminal and a second terminal. The first terminal of the resistor 445 is coupled to the transistor 444. The second terminal of the resistor 445 is coupled to the common terminal, which supplies the common potential.

The transistor 448 has a first terminal, a second terminal, and a control terminal. The first and control terminals of the transistor 448 are coupled to the idle current source circuitry 402 and the transistors 450, 458. The second terminal of the transistor 448 is coupled to the resistor 449. The resistor 449 has a first terminal and a second terminal. The first terminal of the resistor 449 is coupled to the transistor 448. The second terminal of the resistor 449 is coupled to the common terminal, which supplies the common potential.

The transistor 450 has a first terminal, a second terminal, and a control terminal. The first terminal of the transistor 450 is coupled to the transistors 452, 454, 456, 460. The second terminal of the transistor 450 is coupled to the resistor 451. The control terminal of the transistor 450 is coupled to the idle current source circuitry 402 and the transistors 448, 458. The resistor 451 has a first terminal and a second terminal. The first terminal of the resistor 451 is coupled to the transistor 450. The second terminal of the resistor 451 is coupled to the common terminal, which supplies the common potential.

The transistor 452 has a first terminal, a second terminal, and a control terminal. The first terminal of the transistor 452 is coupled to the resistor 453. The second and control terminals of the transistor 452 are coupled to the transistors 450, 454, 456, 460. The resistor 453 has a first terminal and a second terminal. The first terminal of the transistor 452 is coupled to the input supply terminal, which supplies the input supply voltage. The second terminal of the resistor 453 is coupled to the transistor 452.

The transistor 454 has a first terminal, a second terminal, and a control terminal. The first terminal of the transistor 454 is coupled to the resistor 455. The second terminal of the transistor 454 is coupled to the plus side input terminal, which supplies the plus side input signal. The control terminal of the transistor 454 is coupled to the transistors 450, 452, 456, 460. The resistor 455 has a first terminal and a second terminal. The first terminal of the resistor 455 is coupled to the input supply terminal, which supplies the input supply voltage. The second terminal of the resistor 455 is coupled to the transistor 454.

The transistor 456 has a first terminal, a second terminal, and a control terminal. The first terminal of the transistor 456 is coupled to the resistor 457. The second terminal of the transistor 456 is coupled to the minus side input terminal, which supplies the minus side input signal. The control terminal of the transistor 456 is coupled to the 450, 452, 454, 460. The resistor 457 has a first terminal and a second terminal. The first terminal of the resistor 457 is coupled to the input supply terminal, which supplies the input supply voltage. The second terminal of the resistor 457 is coupled to the transistor 456.

The transistor 458 has a first terminal, a second terminal, and a control terminal. The first terminal of the transistor 458 is coupled to the idle current source circuitry 402 and the transistors 448, 450. The second terminal of the transistor 458 is coupled to the resistor 459. The control terminal of the transistor 458 is coupled to the feedback current source circuitry 404. The resistor 459 has a first terminal and a second terminal. The first terminal of the resistor 459 is coupled to the transistor 458. The second terminal of the resistor 459 is coupled to the common terminal, which supplies the common potential.

The transistor 460 has a first terminal, a second terminal, and a control terminal. The first terminal of the transistor 460 is coupled to the input supply terminal, which supplies the input supply voltage. The second terminal of the transistor 460 is coupled to the transistors 450, 452, 454, 456. The control terminal of the transistor 460 is coupled to the input monitor circuitry 412.

The transistor 464 has a first terminal, a second terminal, and a control terminal. The first terminal of the transistor 464 is coupled to the minus side input terminal, which supplies the minus side input signal. The second terminal of the transistor 464 is coupled to the resistor 465. The control terminal of the transistor 464 is coupled to the idle current source circuitry 402, the feedback current source circuitry 404, and the transistors 466, 468. The resistor 465 has a first terminal and a second terminal. The first terminal of the resistor 465 is coupled to the transistor 464. The second terminal of the resistor 465 is coupled to the common terminal, which supplies the common potential.

The transistor 466 has a first terminal, a second terminal, and a control terminal. The first terminal of the transistor 466 is coupled to the plus side input terminal, which supplies the plus side input signal. The second terminal of the transistor 466 is coupled to the resistor 467. The control terminal of the transistor 466 is coupled to the idle current source circuitry 402, the feedback current source circuitry 404, and the transistors 464, 468. The resistor 467 has a first terminal and a second terminal. The first terminal of the resistor 467 is coupled to the transistor 466. The second terminal of the resistor 467 is coupled to the common terminal, which supplies the common potential.

The transistor 468 has a first terminal, a second terminal, and a control terminal. The first terminal of the transistor 468 is coupled to the idle current source circuitry 402, the feedback current source circuitry 404, and the transistors 464, 466. The second terminal of the transistor 468 is coupled to the common terminal, which supplies the common potential. The control terminal of the transistor 468 is coupled to the transistors 470, 472.

The transistor 470 has a first terminal, a second terminal, and a control terminal. The first terminal of the transistor 470 is coupled to the input supply terminal, which supplies the input supply voltage. The second terminal of the transistor 470 is coupled to the transistors 468, 472. The control terminal of the transistor 470 is coupled to the input monitor circuitry 412 and the transistor 472.

The transistor 472 has a first terminal, a second terminal, and a control terminal. The first terminal of the transistor 472 is coupled to the transistors 468, 470. The second terminal of the transistor 472 is coupled to the common terminal, which supplies the common potential. The control terminal of the transistor 472 is coupled to the input monitor circuitry 412 and the transistor 470. In the example of FIG. 4, the transistors 468, 470, 472 are structured as control circuitry to turn on and off the current sink circuitry 408.

The resistor 474 has a first terminal and a second terminal. The first terminal of the resistor 474 is coupled to the plus side input terminal, which supplies the plus side input signal. The second terminal of the resistor 474 is coupled to the common terminal, which supplies the common potential. In some examples, the resistor 474 further has one or more terminals coupled to the common mode voltage control circuitry 414. In such examples, the one or more terminals of the resistor 474 are structured to control the resistance of the resistor 474.

The resistor 476 has a first terminal and a second terminal. The first terminal of the resistor 476 is coupled to the minus side input terminal, which supplies the minus side input signal. The second terminal of the resistor 476 is coupled to the common terminal, which supplies the common potential. In some examples, the resistor 476 further has one or more terminals coupled to the common mode voltage control circuitry 414. In such examples, the one or more terminals of the resistor 476 are structured to control the resistance of the resistor 476.

The noise level circuitry 478 has a first terminal, a second terminal, and a third terminal. The first and second terminals of the noise level circuitry 478 are coupled to the plus and minus side input terminals, which supply the plus and minus side input signals. The third terminal of the noise level circuitry 478 is coupled to the comparison circuitry 480. In some examples, the noise level circuitry 478 is illustrated as amplifier circuitry, which generates an output proportional to an amplitude of the plus and minus input signals.

The comparison circuitry 480 has a first terminal, a second terminal, and a third terminal. The first terminal of the comparison circuitry 480 is coupled to the noise level circuitry 478. The second terminal of the comparison circuitry 480 is coupled to a reference terminal, which supplies a reference noise voltage. The third terminal of the comparison circuitry 480 is coupled to the current source circuitry 406 and the current sink circuitry 408. In some examples, the comparison circuitry 480 is illustrated as a comparator.

The supply monitor circuitry 482 has a first terminal and a second terminal. The first terminal of the supply monitor circuitry 482 is coupled to the output supply terminal, which supplies the output supply voltage. The second terminal of the supply monitor circuitry 482 is coupled to the resistor control circuitry 486. In some examples, the supply monitor circuitry 482 is illustrated as one or more comparators that compare the output supply voltage to different voltage thresholds.

The gain monitor circuitry 484 has a first terminal and a second terminal. The first terminal of the gain monitor circuitry 484 is coupled to the analog gain terminal, which supplies an indication of the analog gain of the class D amplifier circuitry 140, 215. In some examples, the gain monitor circuitry 484 is coupled to a BUS, which supplies the analog gain. In other examples, the gain monitor circuitry 484 is coupled to a register, which sets the analog gain. The second terminal of the gain monitor circuitry 484 is coupled to the resistor control circuitry 486. In some examples, the gain monitor circuitry 484 is illustrated as one or more amplifiers, which generates an output representing a gain.

The resistor control circuitry 486 has a first terminal, a second terminal, a third terminal, and a fourth terminal. The first terminal of the resistor control circuitry 486 is coupled to the supply monitor circuitry 482. The second terminal of the resistor control circuitry 486 is coupled to the gain monitor circuitry 484. The third and fourth terminals of the resistor control circuitry 486 are coupled to the common mode voltage circuitry 410.

In the example of FIG. 4, the transistors 418, 420, 422, 424, 438, 444, 448, 450, 458, 464, 466, 468, 472 are n-channel metal-oxide semiconductor field-effect transistors (MOSFETs). Alternatively, the transistors 418, 420, 422, 424, 438, 444, 448, 450, 458, 464, 466, 468, 472 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. In the example of FIG. 4, the transistors 426, 428, 452, 454, 456, 460, 470 are p-channel MOSFETs. Alternatively, the transistors 426, 428, 452, 454, 456, 460, 470 may be p-channel FETs, p-channel IGBTs, p-channel JFETs, NPN BJTs, or, with slight modifications, N-type equivalent devices. The transistors 418, 420, 422, 424, 426, 428, 438, 444, 448, 450, 452, 454, 456, 458, 460, 470, 464, 466, 468, 472 may be depletion mode devices, drain-extended devices, enhancement mode devices, natural transistors or other type of device structure transistors. Furthermore, the transistors 418, 420, 422, 424, 426, 428, 438, 444, 448, 450, 452, 454, 456, 458, 460, 470, 464, 466, 468, 472 may be implemented in/over a silicon substrate (Si), a silicon carbide substrate (SiC), a gallium nitride substrate (GaN) or a gallium arsenide substrate (GaAs).

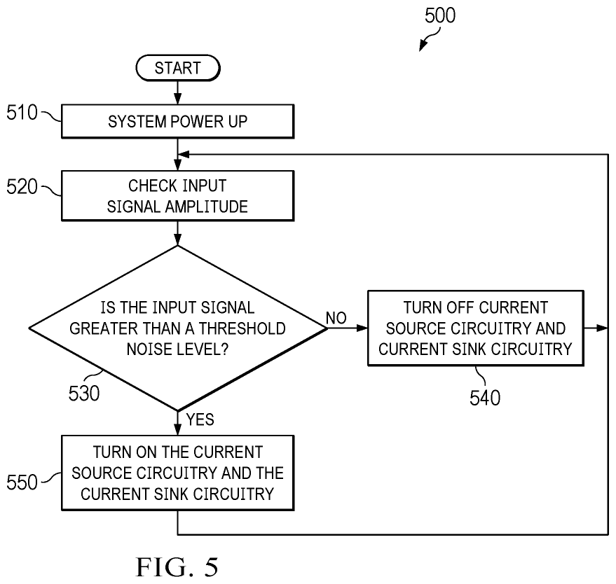

FIG. 5 is a flowchart representative of example operations 500 that may be at least one of executed, instantiated, or performed to implement the input monitor circuitry 360, 412 of FIGS. 3 and 4, or more generally the common mode regulator circuitry 115, 300, 400 of FIGS. 1, 3, and 4. The operations 500 begin at Block 510, at which, the common mode regulator circuitry 115, 300, 400 receives power. (Block 510). In some examples, the common mode regulator circuitry 115, 300, 400 receive the input supply voltage (AVDD) and the output supply voltage (PVDD) at the input supply terminal and the output supply terminal.

The input monitor circuitry 360, 412 checks the input signal amplitude. (Block 520). In some examples, the noise level circuitry 478 of FIG. 4 receives the differential pair of input signals from the input of the class D amplifier circuitry 140, 215 of FIGS. 1 and 2. In such examples, the noise level circuitry 478 determines a noise level of the differential pair of input signals. The comparison circuitry 480 determines the state of the system to be one of a play mode or an idle mode by comparing the determined noise level of the differential pair of input signals to a threshold noise level (NOISE_{REF}). In play mode, the amplitudes of the differential pair of input signals are greater than a threshold. When in play mode, the differential pair of input signals represent an audio signal that is audible. In idle mode, the amplitudes of the differential pair of input signals are less than a threshold. When in idle mode, the differential pair of input signals represent an inaudible signal (e.g., outside of the audible sound spectrum).

The input monitor circuitry 360, 412 determines if the input signal is greater than a threshold noise level. (Block 530). In some examples, the comparison circuitry 480 determines the audio system 100 is in a play mode responsive to the amplitudes of the differential pair of input signals being greater than the noise threshold. In such examples, the comparison circuitry 480 determines the audio system 100 is in an idle mode responsive to the amplitudes of the differential pair of input signals being less than the noise threshold. For example, the comparison circuitry 480 uses a negative sixty decibel (dB) noise threshold to determine if the audio system 100 is in a play or idle mode. The comparison circuitry 480 generates a regulator enable indication responsive to the comparison. In example operations, the comparison circuitry 480 sets the regulator enable indication to a first state (e.g., a logical high, logic one, etc.) responsive to a determination that the audio system 100 is in a play mode and a second state (e.g., a logical low, logic zero, etc.) responsive to a determination that the audio system 100 is in an idle mode.

If the input monitor circuitry 360, 412 determines that the input signal is not greater than the threshold noise level (e.g., Block 530 returns a result of NO), the input monitor circuitry 360, 412 turns off current source circuitry and current sink circuitry. (Block 540). In some examples, the comparison circuitry 480 sets the regulator enable indication to the second state (e.g., a logical low, logic zero, etc.) responsive to determining that the audio system 100 of FIG. 1 is in idle mode. In such examples, the regulator enable indication turns on the transistors 460, 470 of FIG. 4 and turns off the transistor 472 of FIG. 4, which prevents the current source circuitry 406 and the current sink circuitry 408 from supplying or sinking current.

If the input monitor circuitry 360, 412 determines that the input signal is greater than the threshold noise level (e.g., Block 530 returns a result of YES), the input monitor circuitry 360, 412 turns on the current source circuitry and the current sink circuitry. (Block 550). In some examples, the comparison circuitry 480 sets the regulator enable indication to the first state responsive to determining that the audio system 100 is in play mode. In such examples, the regulator enable indication turns off the transistors 460, 470, and turns on the transistor 472, which allows the current source circuitry 406 and the current sink circuitry 408 to supply or sink currents. Control proceeds to return to Block 520. Advantageously, the input monitor circuitry 360, 412 decreases power consumption of the common mode regulator circuitry 115, 300, 400 responsive to turning off the current source circuitry 330, 406 and the current sink circuitry 340, 408 when the audio system 100 is in idle mode.

Although example methods are described with reference to the flowchart illustrated in FIG. 5, many other methods of implementing the input monitor circuitry 360, 412 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

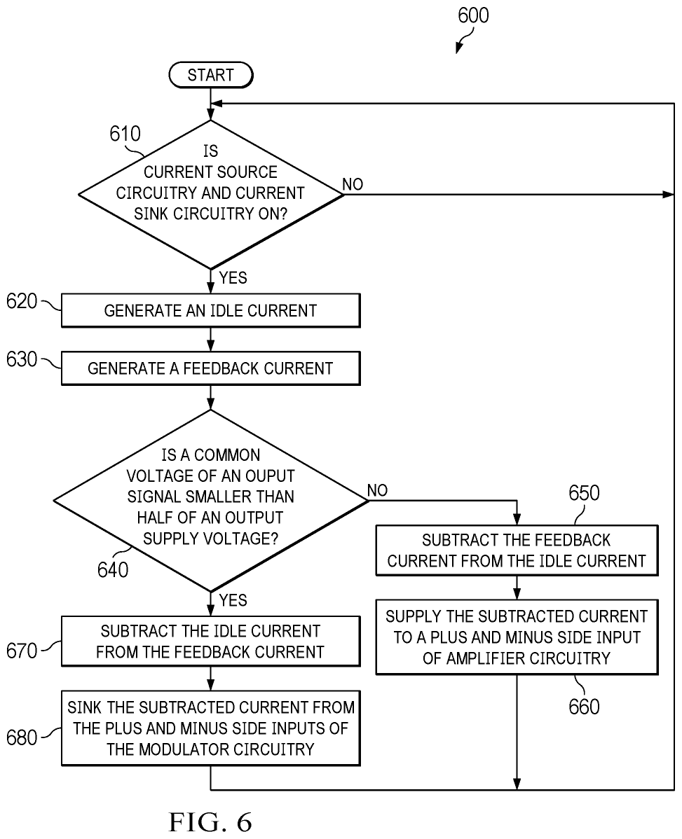

FIG. 6 is a flowchart representative of example operations 600 that may be at least one of executed, instantiated, or performed to implement the common mode regulator circuitry 115, 300, 400 of FIGS. 1, 3, and 4. The operations 600 begin at Block 610, at which, the input monitor circuitry 360, 412 of FIGS. 3 and 4 determines whether or not to turn on current source circuitry and current sink circuitry. (Block 610). The operations 500 of FIG. 5 are example operations of Block 610 of FIG. 6. If the input monitor circuitry 360, 412 turns off the current source circuitry 330, 406 of FIGS. 3 and 4 and the current sink circuitry 340, 408 of FIGS. 3 and 4 (e.g., Block 610 returns a result of NO), control proceeds to return to Block 610.

If the input monitor circuitry 360, 412 turns on the current source circuitry 330, 406 and the current sink circuitry 340, 408 (e.g., Block 610 returns a result of YES), the idle current source circuitry 310, 402 of FIGS. 3 and 4 generates an idle current. (Block 620). In some examples, the idle current (I_{IDLE}) represents the current through the resistors 220, 235 of FIG. 2 when the audio source 105 is not supplying a differential pair of input signals. In example operations, the idle current is proportional to the output supply voltage (PVDD), a gate-to-source voltage of the transistor 418 of FIG. 4 (V_{gs1}), the gate-to-source voltage of the transistor 420 of FIG. 4 (V_{gs2}), and the resistance of the resistor 416 of FIG. 4 (R_{CM}). In some examples, the resistance of the resistor 416 is approximately equal to the resistance of the resistors 220, 235. The idle current may be determined using Equation (1), below. Also, when the gate-to-source voltages of the transistors 418, 420 are equal, Equation (2), below, may be used to determine the idle current. In such example operations, the current through the transistor 420 is proportional to the idle current. Also, the transistors 422, 424, 426, 428 of FIG. 4 mirror the idle current.

$${I}_{IDLE} = \frac{( PVDD - {V}_{gs 1} - {V}_{gs 2} )}{Rcm} \qquad Equation ( 1 )$$

$${I}_{IDLE} = \frac{( PVDD - 2 {V}_{gs 4} )}{Rcm} = \frac{( PVDD / 2 - {V}_{gs 4} )}{Rcm / 2} \qquad Equation ( 2 )$$

The feedback current source circuitry 320, 404 of FIGS. 3 and 4 generates a feedback current. (Block 630). In some examples, the feedback current (I_{FB}) represents the current through the resistors 220, 235 when the audio source 105 is supplying a differential pair of input signals. In example operations, the feedback current is proportional to a common mode voltage of the output signals (V_{outcom}), a gate-to-source voltage of the transistors 438, 444 of FIG. 4 (V_{gs3}), and the resistance of the resistors 436, 437, 442, 443 of FIG. 4 (R_{CM}). The common mode voltage of the output signals is the common mode voltage of the plus side output signal and the minus side output signal from the class D amplifier circuitry 140, 215 and the class AB amplifier circuitry 155, 230. In some examples, the resistances of the resistors 436, 437, 442, 443 are approximately equal to the resistance of the resistors 220, 235. The feedback current may be determined using Equation (3), below. Also, when the audio source 105 is not supplying a differential pair of input signals (e.g., the feedback current is approximately equal to the idle current), Equation (4), below, may be used to determine the feedback current.

$${I}_{FB} = \frac{( {V}_{outcom} - {V}_{gs 3} )}{Rcm / 2} \qquad Equation ( 3 )$$

$${I}_{FB} = \frac{( PVDD / 2 - {V}_{gs 3} )}{Rcm / 2} \qquad Equation ( 4 )$$

The current source circuitry 330, 406 and the current sink circuitry 340, 408 determine if a common mode voltage of an output signal is smaller than half of the output supply voltage. (Block 640). In some examples, the current source circuitry 330, 406 and the current sink circuitry 340, 408 compare the idle current to the feedback current. In such examples, when the current source circuitry 330, 406 and the current sink circuitry 340, 408 determine the idle current is larger than the feedback current, the output common mode voltage is smaller than half of the output supply voltage. Also, when the current source circuitry 330, 406 and the current sink circuitry 340, 408 determine the idle current is smaller than the feedback current, the output common mode voltage is larger than half of the output supply voltage.

If the current source circuitry 330, 406 and the current sink circuitry 340, 408 determine that the common mode voltage of the output signal is smaller than half of the output supply voltage (e.g., Block 640 returns a result of YES), the current source circuitry 330, 406 subtracts the feedback current from the idle current. (Block 650). In example operations of the current source circuitry 330, 406, the idle current source circuitry 402 supplies the idle current to the transistors 448, 458 of FIG. 4. The transistor 458 mirrors the feedback current of the feedback current source circuitry 404 of FIG. 4. When the idle current is less than the feedback current, the transistor 458 sinks the idle current and the transistor 448 has no excess current to sink. When the idle current is greater than the feedback current (e.g., Block 640 returns a result of YES), the transistor 448 sinks a current equal to the idle current minus the feedback current.

The current source circuitry 330, 406 supplies the subtracted current to a plus and minus side inputs of the amplifier circuitry. (Block 660). In example operations, the transistors 450, 452, 454, 456 of FIG. 4 mirror the current through the transistor 448, which is equal to the idle current minus the feedback current. The transistors 454, 456 supply a current equal to the idle current minus the feedback current to the inputs of the class D amplifier circuitry 140, 215. Control proceeds to return to Block 610.

If the current source circuitry 330, 406 and the current sink circuitry 340, 408 determine that the common mode voltage of the output signal is not smaller than half of the output supply voltage (e.g., Block 640 returns a result of NO), the current sink circuitry 340, 408 subtracts the idle current from the feedback current. (Block 670). In example operations of the current sink circuitry 340, 408, the idle current source circuitry 402 sinks the idle current from the resistors 442, 443. The transistor 444 sinks excess current that the idle current source circuitry 402 is not sinking. When the idle current is greater than the feedback current, the idle current source 402 sinks the feedback current from the resistors 442, 443 and the transistor 444 has no excess current to sink. When the idle current is less than the feedback current (e.g., Block 640 returns a result of NO), the transistor 444 sinks a current equal to the feedback current minus the idle current.

The current sink circuitry 340, 408 sinks the subtracted current from the plus and minus side inputs of the amplifier circuitry. (Block 680). In example operations, the transistors 464, 466 of FIG. 4 mirror the current through the transistor 444, which is equal to the feedback current minus the idle current. The transistors 464, 464 sink a current equal to the feedback current minus the idle current from the inputs of the class D amplifier circuitry 140, 215. Control proceeds to return to Block 610.

Although example methods are described with reference to the flowchart illustrated in FIG. 6, many other methods of implementing the common mode regulator circuitry 115, 300, 400 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

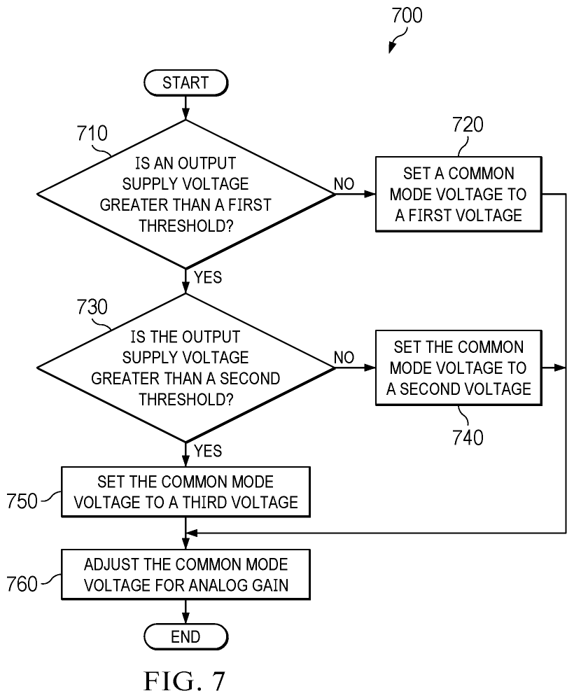

FIG. 7 is a flowchart representative of example operations 700 that may be at least one of executed, instantiated, or performed to implement the common mode voltage control circuitry 370, 414 of FIGS. 3 and 4, or more generally the common mode regulator circuitry 115, 300, 400 of FIGS. 1, 3, and 4. The example operations 700 of FIG. 7 begin at Block 710, at which, the common mode voltage control circuitry 370, 414 determines if an output supply voltage is greater than a first threshold. (Block 710). In some examples, the supply monitor circuitry 482 of FIG. 4 compares the output supply voltage (PVDD) to a first threshold voltage.

If the common mode voltage control circuitry 370, 414 determines that the output supply voltage is not greater than the first threshold (e.g., Block 710 returns a result of NO), the common mode voltage control circuitry 370, 414 sets a common mode voltage to a first voltage. (Block 720). In some examples, the resistor control circuitry 486 of FIG. 4 supplies first trim codes to the resistors 474, 476 of FIG. 4 responsive to the supply monitor circuitry 482 determining that the output supply voltage is less than the first threshold voltage. In such examples, the trim codes set the resistances of the resistors 474, 476 and set the common mode voltage of the differential pair of amplifier input signals to a first voltage. Advantageously, the resistors 474, 476 set the common mode voltage at inputs of the class D amplifier circuitry 140, 215 of FIGS. 1 and 2.

If the common mode voltage control circuitry 370, 414 determines that the output supply voltage is greater than the first threshold (e.g., Block 710 returns a result of YES), the common mode voltage control circuitry 370, 414 determines if the output supply voltage is greater than a second threshold. (Block 730). In some examples, the supply monitor circuitry 482 compares the output supply voltage to a second threshold voltage responsive to determining that the output supply voltage is greater than the first threshold voltage.

If the common mode voltage control circuitry 370, 414 determines that the output supply voltage is not greater than the second threshold (e.g., Block 730 returns a result of NO), the common mode voltage control circuitry 370, 414 sets a common mode voltage to a second voltage. (Block 740). In some examples, the resistor control circuitry 486 supplies second trim codes to the resistors 474, 476 responsive to the supply monitor circuitry 482 determining that the output supply voltage is between the first and second threshold voltages. In such examples, the trim codes set the resistances of the resistors 474, 476 and set the common mode voltage of the differential pair of amplifier input signals to a second voltage.

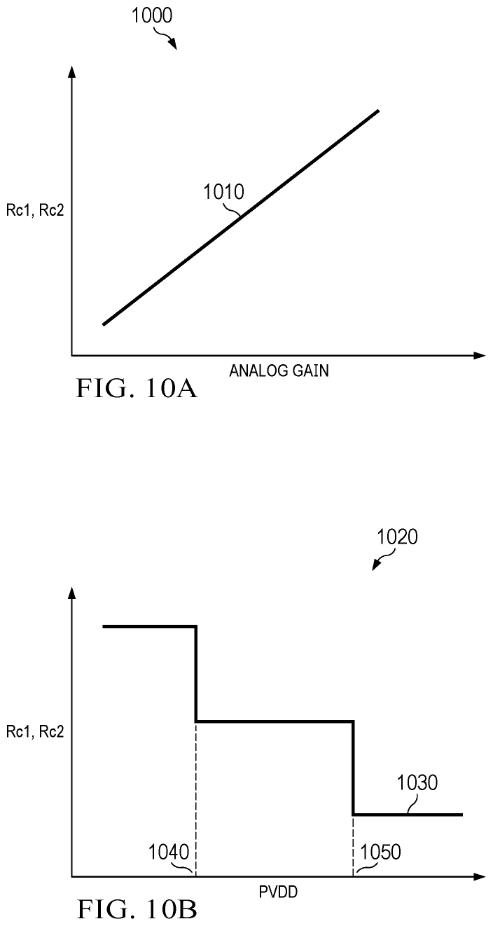

If the common mode voltage control circuitry 370, 414 determines that the output supply voltage is greater than the second threshold (e.g., Block 730 returns a result of YES), the common mode voltage control circuitry 370, 414 sets a common mode voltage to a third voltage. (Block 750). In some examples, the resistor control circuitry 486 supplies third trim codes to the resistors 474, 476 responsive to the supply monitor circuitry 482 determining that the output supply voltage is greater than the second threshold voltage. In such examples, the trim codes set the resistances of the resistors 474, 476 and set the common mode voltage of the differential pair of amplifier input signals to a third voltage. Example adjustments of the resistors 474, 476 responsive to output supply voltage are illustrated and described in connection with FIG. 10B, below.

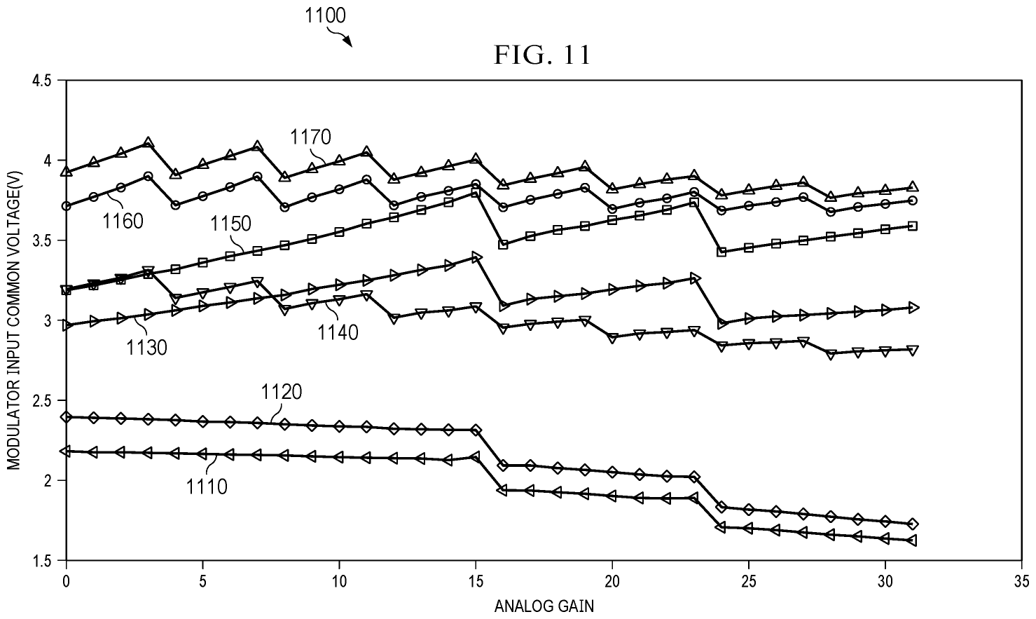

The common mode voltage control circuitry 370, 414 adjusts the common mode voltage for analog gain. (Block 760). In some examples, the gain monitor circuitry 484 of FIG. 4 receives an indication of the analog gain of the class D amplifier circuitry 140, 215 by the analog gain terminal. In other examples, the gain monitor circuitry 484 determines an analog gain of the class D amplifier circuitry 140, 215 responsive to comparing amplitudes of the differential pair of input signals (INP, INM) to amplitudes of the differential pair of output signals (OUTP, OUTM). The resistor control circuitry 486 increases the resistances of the resistors 474, 476 as the analog gain increases. Example adjustments of the resistors 474, 476 responsive to changes in the analog gain are illustrated and described in connection with FIG. 10A, below. Control proceeds to end. Advantageously, the common mode voltage control circuitry 370, 414 adjusts the common mode voltage at inputs of the class D amplifier circuitry 140, 215 responsive to the output supply voltage and the analog gain. Advantageously, as illustrated in FIG. 11, the common mode voltage control circuitry 370, 414 increases a range of operating conditions of the common mode regulator circuitry 115, 300, 400 of FIGS. 1, 3, and 4.

Although example methods are described with reference to the flowchart illustrated in FIG. 7, many other methods of implementing the common mode voltage control circuitry 370, 414 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

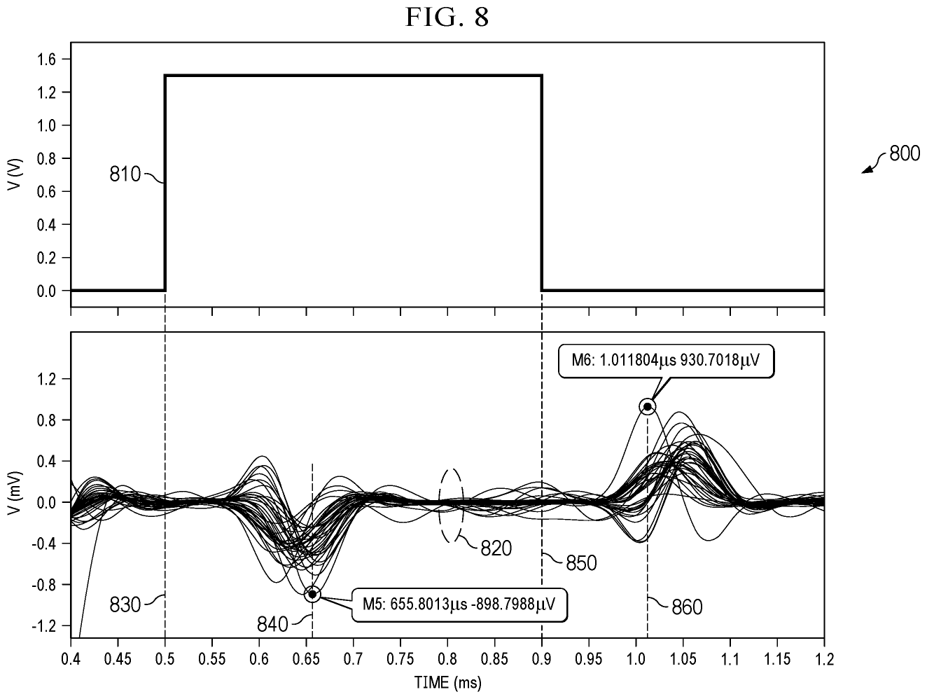

FIG. 8 is a plot 800 of example turn on and turn off operations of the multi-class modulation circuitry 110, 200 of FIGS. 1 and 2 with the common mode regulation circuitry 115, 300, 400 of FIGS. 1, 3, and 4. The example plot 800 of FIG. 8 illustrates an example activation signal 810 and example common mode voltages 820 over time. The activation signal 810 represents whether the common mode regulation circuitry 115, 300, 400 is on or off. In the example of FIG. 8, the activation signal 810 represents the common mode regulation circuitry 115, 300, 400 being on as a logic high (e.g., logical one) and being off as a logic low (e.g., logical zero). The common mode voltages 820 represent a plurality of samples of a common mode voltage between the plus and minus side input terminals, which supply the plus and minus side input voltages.

At a first time 830, the input monitor circuitry 360, 412 of FIGS. 3 and 4 turns on the current source circuitry 330, 406 of FIGS. 3 and 4 and the current sink circuitry 340, 408 of FIGS. 3 and 4. At a second time 840, the common mode voltages 820 have vary by approximately sixty-six hundredths of a millivolt responsive to the input monitor circuitry 360, 412 turning on the common mode regulator circuitry 115, 300, 400. Alternatively, in some designs that utilize an error amplifier the common mode voltage varies by thirteen milli volts. At a third time 850, the input monitor circuitry 360, 412 of FIGS. 3 and 4 turns off the current source circuitry 330, 406 and the current sink circuitry 340, 408. At a fourth time 860, the common mode voltages 820 have vary by approximately ninety-three hundredths of a millivolt responsive to the input monitor circuitry 360, 412 turning off the common mode regulator circuitry 115, 300, 400. Advantageously, the common mode regulator circuitry 115, 300, 400 reduces the variation of the common mode voltages 820 when turning on and off the current source circuitry 330, 406 and the current sink circuitry 340, 408.

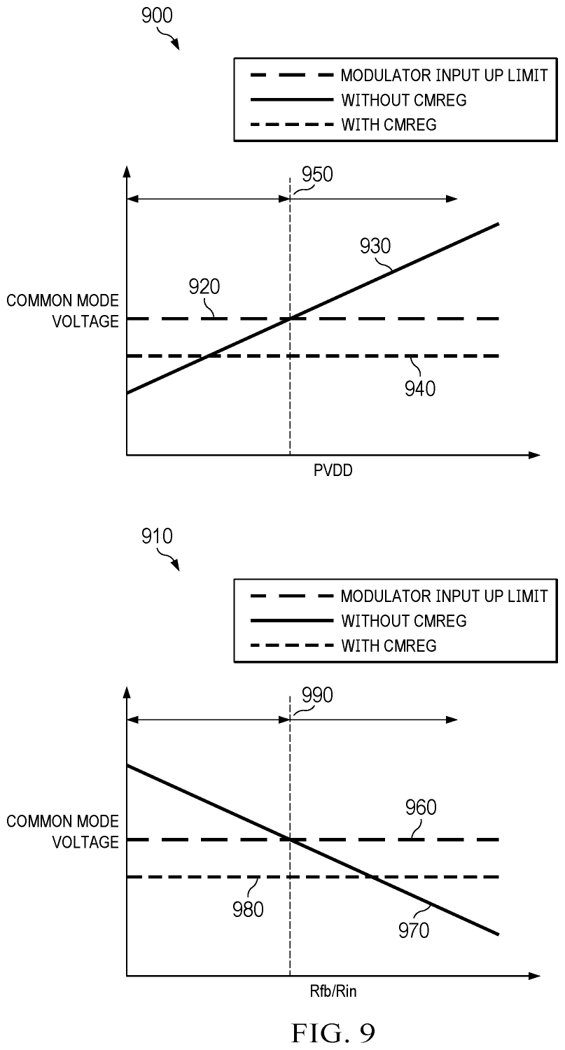

FIG. 9 illustrates a first example plot 900 and a second example plot 910 of example common mode voltages of the multi-class modulation circuitry 110 of FIGS. 1 and 2 with and without the common mode regulator circuitry 115, 300, 400 of FIGS. 1, 3, and 4. The example plot 900 of FIG. 9 illustrates an example common mode limit 920, an example unregulated common mode voltage 930, and an example regulated common mode voltage 940 across a range of output supply voltages (PVDD). The common mode limit 920 represents a maximum common mode voltage of signals supplied to the class D amplifier circuitry 140, 215 of FIGS. 1 and 2. In example operations, the class D amplifier circuitry 140, 215 inaccurately generates an output responsive to input signals having a common mode voltage greater than the common mode limit 920. The unregulated common mode voltage 930 represents a common mode voltage of signals supplies to the class D amplifier circuitry 140, 215 when the common mode regulator circuitry 115, 300, 400 is off. The regulated common mode voltage 940 represents a common mode voltage of signals supplies to the class D amplifier circuitry 140, 215 when the common mode regulator circuitry 115, 300, 400 is on.

In the example operations of FIG. 9, when the output supply voltage is greater than a reference voltage 950, the class D amplifier circuitry 140, 215 fails to generate an accurate output responsive to the unregulated common mode voltage 930. Advantageously, the common mode regulator circuitry 115, 300, 400 sources and sinks currents from the input of the class D amplifier circuitry 140, 215 to generate the regulated common mode voltage 940.

The example plots 910 of FIG. 9 illustrates an example common mode limit 960, an example unregulated common mode voltage 970, and an example regulated common mode voltage 980 across a range of analog gains of the class D amplifier circuitry 140, 215. The common mode limit 960 represents a maximum common mode voltage of signals supplied to the class D amplifier circuitry 140, 215. In example operations, the class D amplifier circuitry 140, 215 inaccurately generates an output responsive to input signals having a common mode voltage greater than the common mode limit 960. The unregulated common mode voltage 970 represents a common mode voltage of signals supplies to the class D amplifier circuitry 140, 215 when the common mode regulator circuitry 115, 300, 400 is off. The regulated common mode voltage 980 represents a common mode voltage of signals supplies to the class D amplifier circuitry 140, 215 when the common mode regulator circuitry 115, 300, 400 is on.

In the example operations of FIG. 9, when the ratio of the resistors 220, 240 of FIG. 2, which sets an analog gain, is greater than a reference ratio 990, the class D amplifier circuitry 140, 215 fails to generate an accurate output responsive to the unregulated common mode voltage 970. Advantageously, the common mode regulator circuitry 115, 300, 400 adjusts the resistances of the resistors 474, 476 of FIG. 4 to generate the regulated common mode voltage 980.

FIG. 10A is a plot 1000 of example common mode resistances 1010 of the multi-class modulation circuitry 110, 200 of FIGS. 1 and 2 across a range of analog gains that are set by the common mode regulation circuitry 115, 300, 400 of FIGS. 1, 3, and 4. In example operations, the common mode voltage control circuitry 370, 414 of FIGS. 3 and 4 increase the resistances of the common mode voltage circuitry 350, 410 of FIGS. 3 and 4 as the analog gain increases. Advantageously, the common mode voltage control circuitry 370, 414 adjusts the common mode voltage circuitry 350, 410 to compensate for variations in analog gain of the class D amplifier circuitry 140, 215 of FIGS. 1 and 2.

FIG. 10B is a plot 1020 of example common mode resistances 1030 of the common mode regulation circuitry 115, 300, 400 of FIGS. 1, 3, and 4 across a range of output supply voltages (PVDD). In example operation, the common mode voltage control circuitry 370, 414 of FIGS. 3 and 4 compares the output supply voltage to a first threshold voltage 1040 and a second threshold voltage 1050. The common mode voltage control circuitry 370, 414 sets the resistances of the common mode voltage circuitry 350, 410 of FIGS. 3 and 4 to first values responsive to the output supply voltage being less than the first threshold voltage 1040. The common mode voltage control circuitry 370, 414 sets the resistances of the common mode voltage circuitry 350, 410 to second values responsive to the output supply voltage being between the threshold voltages 1040 and 1050. The common mode voltage control circuitry 370, 414 sets the resistances of the common mode voltage circuitry 350, 410 to third values responsive to the output supply voltage being greater than the second threshold voltage 1050. Advantageously, the common mode voltage control circuitry 370, 414 adjusts the common mode voltage circuitry 350, 410 to compensate for variations in analog gain of the class D amplifier circuitry 140, 215 of FIGS. 1 and 2.

FIG. 11 is a plot 1100 of example common mode voltages of the common mode regulator circuitry 115, 300, 400 of FIGS. 1, 3, and 4 across a range of analog gains and common mode voltages of the multi-class modulation circuitry 110, 200 of FIGS. 1 and 2. The example plot 1100 illustrates a first example common mode 1110, a second example common mode 1120, a third example common mode 1130, a fourth example common mode 1140, a fifth example common mode 1150, a sixth example common mode 1160, and a seventh example common mode 1170.

The common mode 1110 represents an example common mode voltage of the plus and minus input voltages at the plus and minus input terminals of the class D amplifier circuitry 140, 215 of FIGS. 1 and 2 when the input supply voltage and the output supply voltage are four and a half volts.

The common mode 1120 represents an example common mode voltage of the plus and minus input voltages at the plus and minus input terminals when the input supply voltage is five volts and the output supply voltage is four and a half volts.

The common mode 1130 represents an example common mode voltage of the plus and minus input voltages at the plus and minus input terminals when the input supply voltage is five volts and the output supply voltage is four and a fourteen and four-tenths volts.

The common mode 1140 represents an example common mode voltage of the plus and minus input voltages at the plus and minus input terminals when the input supply voltage is five volts and the output supply voltage is sixteen and one-tenth volts.

The common mode 1150 represents an example common mode voltage of the plus and minus input voltages at the plus and minus input terminals when the input supply voltage is five volts and the output supply voltage is fifteen and a nine-tenths volts.

The common mode 1160 represents an example common mode voltage of the plus and minus input voltages at the plus and minus input terminals when the input supply voltage is five volts and the output supply voltage is twenty-six and four-tenths volts.

The common mode 1170 represents an example common mode voltage of the plus and minus input voltages at the plus and minus input terminals when the input supply voltage is five and a half volts and the output supply voltage is twenty-six and four-tenths volts.

Advantageously, the common mode regulator circuitry 115, 300, 400 may regulate the common mode voltage of at the input of the class D amplifier circuitry 140, 215 across a wide range of operating conditions.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind and that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” refers to implementations including any of (1) at least one A, (2) at least one B, or (3) at least one A and at least one B. Similarly, as used herein in the context of describing structures, components, items, objects and/or things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real-world imperfections. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather also includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to configure or structure the FPGAs to instantiate one or more operations and functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “and/or” (when used in a form such as A, B and/or C) refers to any combination or subset of A, B, C, such as: (a) A alone; (b) B alone; (c) C alone; (d) A with B; (e) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Numerical identifiers such as “first,” “second,” “third,” etc. are used merely to distinguish between elements of substantially the same type in terms of structure and/or function. These identifiers as used in the detailed description do not necessarily align with those used in the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. An apparatus comprising:
current source circuitry having a first terminal, a second terminal, a third terminal, and a fourth terminal;
current sink circuitry having a first terminal, a second terminal, a third terminal, and a fourth terminal;
common mode voltage circuitry having a first terminal and a second terminal, the first terminal of the common mode voltage circuitry coupled to the first terminal of the current source circuitry and the first terminal of the current sink circuitry, the second terminal of the common mode voltage circuitry coupled to the second terminal of the current source circuitry and the second terminal of the current sink circuitry;
idle current source circuitry having a first terminal and a second terminal, the first terminal of the idle current source circuitry coupled to the third terminal of the current source circuitry; and
feedback current source circuitry having a first terminal, a second terminal, and a third terminal, the first terminal of the feedback current source circuitry is coupled to the fourth terminal of the current source circuitry, the second terminal of the feedback current source circuitry is coupled to the second terminal of the current sink circuitry, the third terminal of the feedback current source circuitry coupled to the fourth terminal of the current sink circuitry and the second terminal of the idle current source circuitry.

2. The apparatus of claim 1, wherein the feedback current source circuitry further has a third terminal, the apparatus further comprising
a resistor having a first terminal and a second terminal; and
amplifier circuitry having a first terminal, a second terminal, and third terminal, the first terminal of the amplifier circuitry coupled to the first terminal of the current source circuitry, the first terminal of the current sink circuitry, the first terminal of the common mode voltage circuitry, and the first terminal of the resistor, the second terminal of the amplifier circuitry coupled to the second terminal of the current source circuitry, the second terminal of the current sink circuitry, and the second terminal of the common mode voltage circuitry, the third terminal of the amplifier circuitry coupled to the third terminal of the current source circuitry and the second terminal of the resistor.

3. The apparatus of claim 2, wherein the feedback current source circuitry includes:
first feedback current mirror circuitry having a first terminal and a second terminal, the first terminal of the first feedback current mirror circuitry coupled to the fourth terminal of the current source circuitry; and
second feedback current mirror circuitry having a first terminal, a second terminal, and a third terminal, the first terminal of the second feedback current mirror circuitry coupled to the third terminal of the amplifier circuitry, the second terminal of the resistor, and the second terminal of the first feedback current mirror circuitry, the second terminal of the second feedback current mirror circuitry coupled to the third terminal of the current source circuitry, and the third terminal of the second feedback current mirror circuitry coupled to the fourth terminal of the current sink circuitry and the second terminal of the idle current source circuitry.

4. The apparatus of claim 3, wherein the resistor is a first resistor, the first feedback current mirror circuitry includes:
a second resistor having a first terminal and a second terminal, the first terminal of the second resistor is coupled to the third terminal of the amplifier circuitry, the second terminal of the first resistor, and the first terminal of the second feedback current mirror circuitry; and
a transistor having a first terminal and a control terminal coupled to the fourth terminal of the current source circuitry and the second terminal of the second resistor.

5. The apparatus of claim 1, wherein the current source circuitry includes:
a first transistor having a first terminal and a control terminal;
a second transistor having a first terminal and a control terminal;
a third transistor having a first terminal and a control terminal, the first terminal of the third transistor coupled to the first terminal of the idle current source circuitry, the first terminal and control terminal of the first transistor, and the control terminal of the second transistor, the control terminal of the third transistor coupled to the first terminal of the feedback current source circuitry;
a fourth transistor having a first terminal and a control terminal;
a fifth transistor having a first terminal and a control terminal, the first terminal of the fifth transistor coupled to the first terminal of the current sink circuitry and the first terminal of the common mode voltage circuitry; and
a sixth transistor having a first terminal and a control terminal, the first terminal of the sixth transistor coupled to the second terminal of the current sink circuitry and the second terminal of the common mode voltage circuitry, the control terminal of the sixth transistor coupled to the first terminal of the second transistor, the first terminal and the control terminal of the fourth transistor, and the control terminal of the fifth transistor.

6. The apparatus of claim 1, wherein the current sink circuitry includes:
a first transistor having a first terminal and a control terminal, the first terminal of the first transistor coupled to the first terminal of the current source circuitry and the first terminal of the common mode voltage circuitry; and
a second transistor having a first terminal and a control terminal, the first terminal of the second transistor coupled to the second terminal of the current source circuitry and the second terminal of the common mode voltage circuitry, the control terminal of the current sink circuitry coupled to the second terminal of the feedback current source circuitry and the control terminal of the first transistor.

7. The apparatus of claim 1, wherein the idle current source circuitry includes:
a first transistor having a first terminal and a control terminal;
a second transistor having a first terminal and a control terminal;
a third transistor having a first terminal and a control terminal, the first terminal of the third transistor coupled to the third terminal of the current source circuitry, the control terminal of the third transistor coupled to the first terminal of the first transistor and the first terminal and control terminal of the second transistor;
a fourth transistor having a first terminal and a control terminal; and
a fifth transistor having a first terminal and a control terminal, the first terminal of the fifth transistor coupled to the fourth terminal of the current sink circuitry and the third terminal of the feedback current source circuitry, the control terminal of the fifth transistor coupled to the control terminal of the first transistor and the first terminal and the control terminal of the fourth transistor.

8. The apparatus of claim 1, wherein the current source circuitry further has a fifth terminal, the current sink circuitry further has a fifth terminal, and the apparatus further comprising input monitor circuitry having a first terminal, a second terminal, and a third terminal, the first terminal of the input monitor circuitry coupled to the first terminal of the current source circuitry, the first terminal of the current sink circuitry, and the first terminal of the common mode voltage circuitry, the second terminal of the input monitor circuitry coupled to the second terminal of the current source circuitry, the second terminal of the current sink circuitry, and the second terminal of the common mode voltage circuitry, the third terminal of the input monitor circuitry coupled to the fifth terminal of the current source circuitry and the fifth terminal of the current sink circuitry.

9. The apparatus of claim 1, wherein the common mode voltage circuitry further has a third terminal and a fourth terminal, and the apparatus further comprising common mode voltage control circuitry having a first terminal, a second terminal, a third terminal, and a fourth terminal, the first terminal of the common mode voltage control circuitry is coupled to the first terminal of the current source circuitry, the first terminal of the current sink circuitry, and the first terminal of the common mode voltage circuitry, the second terminal of the common mode voltage control circuitry coupled to the first terminal of the current source circuitry, the first terminal of the current sink circuitry, and the second terminal of the common mode voltage circuitry, the third terminal of the common mode voltage control circuitry coupled to the third terminal of the common mode voltage circuitry, and the fourth terminal of the common mode voltage control circuitry coupled to the fourth terminal of the common mode voltage circuitry.

10. An apparatus comprising:
amplifier circuitry having a first terminal, a second terminal, and a third terminal;
a resistor having a first terminal and a second terminal the first terminal of the resistor coupled to the first terminal of the amplifier circuitry; and
common mode regulator circuitry including:
current source circuitry having a first terminal and a second terminal;
current sink circuitry having a first terminal and a second terminal; and
common mode voltage circuitry having a first terminal and a second terminal,
the first terminal of the common mode voltage circuitry coupled to the second terminal of the amplifier circuitry, the second terminal of the resistor, the first terminal of the current source circuitry, and the first terminal of the current sink circuitry, the second terminal of the common mode voltage circuitry coupled to the third terminal of the amplifier circuitry, the second terminal of the current source circuitry, and the second terminal of the current sink circuitry.

11. The apparatus of claim 10, wherein the current source circuitry further has a third terminal and a fourth terminal, the current sink circuitry further has a third terminal and a fourth terminal, and the common mode regulator circuitry further includes:
idle current source circuitry having a first terminal and a second terminal, the first terminal of the idle current source circuitry coupled to the third terminal of the current source circuitry;
first feedback current mirror circuitry having a first terminal, and a second terminal, the first terminal of the first feedback current mirror circuitry coupled to fourth terminal of the current source circuitry; and
second feedback current mirror circuitry having a first terminal, a second terminal, and a third terminal, the first terminal of the second feedback current mirror circuitry coupled to the first terminal of the amplifier circuitry, the first terminal of the resistor, and the second terminal of the first feedback current mirror circuitry, the second terminal of the second feedback current mirror circuitry coupled to the third terminal of the current sink circuitry, the third terminal of the second feedback current mirror circuitry coupled to the fourth terminal of the current sink circuitry and the second terminal of the idle current source circuitry.

12. The apparatus of claim 11, wherein the resistor is a first resistor, and the second feedback current mirror circuitry includes:
a second resistor having a first terminal and a second terminal, the first terminal of the second resistor coupled to the first terminal of the amplifier circuitry, the first terminal of the first resistor, and the second terminal of the first feedback current mirror circuitry; and
a transistor having a first terminal and a control terminal coupled to the second terminal of the idle current source circuitry, the fourth terminal of the current sink circuitry, and the second terminal of the second resistor.

13. The apparatus of claim 11, wherein the idle current source circuitry includes:
a first transistor has a first terminal and a control terminal, the first terminal of the first transistor coupled to the third terminal of the current source circuitry;
a second transistor has a first terminal and a control terminal;
a third transistor has a first terminal and a control terminal, the first terminal of the third transistor coupled to the fourth terminal of the current sink circuitry and the third terminal of the second feedback current mirror circuitry; and
a fourth transistor has a first terminal and a control terminal, the first terminal of the fourth transistor coupled to the control terminal of the first transistor and the first terminal and the control terminal of the second transistor, the control terminal of the fourth transistor coupled to the control terminal of the third transistor.

14. The apparatus of claim 10, wherein the current source circuitry further has a third terminal, the current sink circuitry further has a third terminal, and the apparatus is further comprising input monitor circuitry including:
noise level circuitry having a first terminal, a second terminal, and a third terminal, the first terminal of the noise level circuitry coupled to the first terminal of the current source circuitry, the first terminal of the current sink circuitry, and the first terminal of the common mode voltage circuitry, the second terminal of the noise level circuitry coupled to the second terminal of the current source circuitry, the second terminal of the current sink circuitry, and the second terminal of the common mode voltage circuitry; and
comparison circuitry having a first terminal and a second terminal, the first terminal of the comparison circuitry coupled to the third terminal of the noise level circuitry, the second terminal of the comparison circuitry coupled to the third terminal of the current source circuitry and the third terminal of the current sink circuitry.

15. The apparatus of claim 10, wherein the common mode voltage circuitry further has a third terminal and a fourth terminal, and the apparatus is further comprising common mode voltage control circuitry including:
supply monitor circuitry having a terminal;
gain monitor circuitry having a first terminal, a second terminal, and a third terminal, the first terminal of the gain monitor circuitry coupled to the first terminal of the current source circuitry, the first terminal of the current sink circuitry, and the first terminal of the common mode voltage circuitry, the second terminal of the gain monitor circuitry coupled to the second terminal of the current source circuitry, the second terminal of the current sink circuitry, and the second terminal of the common mode voltage circuitry; and
resistor control circuitry having a first terminal, a second terminal, a third terminal, and a fourth terminal, the first terminal of the resistor control circuitry coupled to the terminal of the supply monitor circuitry, the second terminal of the resistor control circuitry coupled to the third terminal of the gain monitor circuitry, the third terminal of the resistor control circuitry coupled to the third terminal of the common mode voltage circuitry, the fourth terminal of the resistor control circuitry coupled to the fourth terminal of the common mode voltage circuitry.

16. An apparatus comprising:
amplifier circuitry having an input and an output, the amplifier circuitry configured to generate an output signal at the output responsive to an input signal received at the input;
a resistor coupled between the input of the amplifier circuitry and the output of the amplifier circuitry; and
common mode regulator circuitry coupled to the input of the amplifier circuitry and to the resistor, the common mode regulator circuitry configured to:
set a common mode voltage of the input of the amplifier circuitry;
supply a first current to compensate the common mode voltage responsive to currents of the resistor; and
sink a second current to compensate the common mode voltage responsive to currents of the resistor.

17. The apparatus of claim 16, wherein the common mode regulator circuitry is further configured to:
generate a third current proportional to a current of the resistor responsive to no input signal being received at the input of the amplifier circuitry; and
generate a fourth current proportional to a current of the resistor responsive to the amplifier circuitry generating the output signal.

18. The apparatus of claim 17, wherein the common mode regulator circuitry is further configured to generate the first current responsive to subtracting the fourth current from the third current and a common mode voltage of the output signal being less than a reference voltage.

19. The apparatus of claim 17, wherein the common mode regulator circuitry is further configured to generate the second current responsive to subtracting the third current from the fourth current and a common mode voltage of the output signal being greater than a reference voltage.

20. The apparatus of claim 16, wherein the common mode regulator circuitry is further configured to:
determine an amplitude of the input signal;
compare the amplitude of the input signal to a threshold noise level; and
supply and sink currents at the input of the amplifier circuitry responsive to the comparison.
